(19) United States
(12) Patent Application Publication
(10) Pub. No.: US 2024/0105451 A1
(43) Pub. Date: Mar. 28, 2024

(54) SEMICONDUCTOR SUBSTRATE MANUFACTURING METHOD AND COMPOSITION

(71) Applicant: JSR CORPORATION, Tokyo (JP)

(72) Inventors: Eiji YONEDA, Tokyo (JP); Takayoshi ABE, Tokyo (JP); Hiroyuki MIYAUCHI, Tokyo (JP)

(73) Assignee: JSR CORPORATION, Tokyo (JP)

(21) Appl. No.: 18/509,611

(22) Filed: Nov. 15, 2023

Related U.S. Application Data
(63) Continuation-in-part of application No. PCT/JP2022/020145, filed on May 13, 2022.

(30) Foreign Application Priority Data
May 19, 2021 (JP) 2021-084489
Aug. 10, 2021 (JP) 2021-130468

(51) Int. Cl. H01L 21/027; G03F 7/20; G03F 7/32

(52) U.S. Cl. CPC H01L 21/0277; G03F 7/2004; G03F 7/32

(57) ABSTRACT

A method for manufacturing a semiconductor substrate, includes: directly or indirectly applying a composition for forming a resist underlayer film to a substrate to form a resist underlayer film; applying a composition for forming a resist film to the resist underlayer film to form a resist film; exposing the resist film to radiation; and developing the exposed resist film. The composition for forming a resist underlayer film includes: a polymer; an acid generating agent; and a solvent. The resist underlayer film has a film thickness of 6 nm or less.

### CROSS-REFERENCE TO RELATED APPLICATIONS

The present application is a continuation-in-part application of International Patent Application No. PCT/JP2022/020145 filed May 13, 2022, which claims priority to Japanese Patent Application No. 2021-084489 filed May 19, 2021, and to Japanese Patent Application No. 2021-130468 filed Aug. 10, 2021. The contents of these applications are incorporated herein by reference in their entirety.

### TECHNICAL FIELD

### Background of the Disclosure

The present disclosure relates to a method for manufacturing a semiconductor substrate and a composition.

### Background Art

A semiconductor device is produced using, for example, a multilayer resist process in which a resist pattern is formed by exposing and developing a resist film laminated on a substrate with a resist underlayer film, such as an organic underlayer film or a silicon-containing film, being interposed between them. In this process, the resist underlayer film is etched using this resist pattern as a mask, and the substrate is further etched using the obtained resist underlayer film pattern as a mask so that a desired pattern is formed on the semiconductor substrate.

In recent years, highly enhanced integration of semiconductor devices has further advanced, and exposure light to be used tends to have a shorter wavelength, as from a KrF excimer laser beam (248 nm) or an ArF excimer laser beam (193 nm) to an extreme ultraviolet ray (13.5 nm; hereinafter also referred to as “EUV”). Various studies have been conducted on compositions for forming a resist underlayer film in such EUV exposure (see WO 2013/141015 A).

### SUMMARY

According to an aspect of the present disclosure, a method for manufacturing a semiconductor substrate, includes: directly or indirectly applying a composition for forming a resist underlayer film to a substrate to form a resist underlayer film; applying a composition for forming a resist film to the resist underlayer film to form a resist film; exposing the resist film to radiation; and developing the exposed resist film. The composition for forming a resist underlayer film includes: a polymer; an acid generating agent; and a solvent. The resist underlayer film has a film thickness of 6 nm or less.

According to another aspect of the present disclosure, a composition is suitable for forming a resist underlayer film having a film thickness of 6 nm or less. The composition includes: a polymer; an acid generating agent; and a solvent.

### DESCRIPTION OF THE EMBODIMENTS

As used herein, the words “a” and “an” and the like carry the meaning of “one or more.” When an amount, concentration, or other value or parameter is given as a range, and/or its description includes a list of upper and lower values, this is to be understood as specifically disclosing all integers and fractions within the given range, and all ranges formed from any pair of any upper and lower values, regardless of whether subranges are separately disclosed. Where a range of numerical values is recited herein, unless otherwise stated, the range is intended to include the endpoints thereof, as well as all integers and fractions within the range. As an example, a stated range of 1-10 fully describes and includes the independent subrange 3.4-7.2 as does the following list of values: 1, 4, 6, 10.

While the line width of a resist pattern formed through exposure to extreme ultraviolet rays and development is being miniaturized to a level of 20 nm or less, there is a request for pattern rectangularity of securing rectangularity of a resist pattern by inhibiting trailing of a pattern at a bottom part of a resist film.

The present disclosure relates to, in one embodiment, a method for manufacturing a semiconductor substrate, the method including:
directly or indirectly applying a composition for forming a resist underlayer film to a substrate;
applying a composition for forming a resist film to the resist underlayer film formed by applying the composition for forming a resist underlayer film;
exposing the resist film formed by applying the composition for forming a resist film to radiation; and
developing at least the exposed resist film,
wherein the composition for forming a resist underlayer film contains:
a polymer (hereinafter, also referred to as a “polymer [A]”);
an acid generating agent (hereinafter, also referred to as an “acid generating agent [B]”); and
a solvent (hereinafter, also referred to as a “solvent [C]”), and
the resist underlayer film has a film thickness of 6 nm or less.

In another embodiment, the present disclosure relates to:
a composition for forming a resist underlayer film suitable for forming a resist underlayer film having a film thickness of 6 nm or less, the composition for forming a resist underlayer film including:
a polymer;
an acid generating agent; and
a solvent.

By the method for manufacturing a semiconductor substrate, it is possible to efficiently manufacture a semiconductor substrate because of using a composition for forming a resist underlayer film capable of forming a resist underlayer film superior in pattern rectangularity. When the composition for forming a resist underlayer film is used, a film superior in pattern rectangularity can be formed. Therefore, they can suitably be used for, for example, producing semiconductor devices expected to be further microfabricated in the future.

Hereinafter, a method for manufacturing a semiconductor substrate and a composition for forming a resist underlayer film according to each embodiment of the present disclosure will be described in detail. Combinations of suitable modes in the embodiments are also preferred.

### Method for Manufacturing Semiconductor Substrate

The method for manufacturing a semiconductor substrate includes directly or indirectly applying a composition for forming a resist underlayer film to a substrate (this step is hereinafter also referred to as “application step (I) ”); applying a composition for forming a resist film to the resist underlayer film formed by applying the composition for forming a resist underlayer film (this step is hereinafter also referred to as “application step (II)”); exposing the resist film formed by applying the composition for forming a resist film to radiation (this step is hereinafter also referred to as “exposure step”); and developing at least the exposed resist film (this step is hereinafter also referred to as “development step”).

By the method for manufacturing a semiconductor substrate, a resist underlayer film superior in pattern rectangularity can be formed due to the use of a prescribed composition for forming a resist underlayer film in the application step (I), so that a semiconductor substrate having a favorable pattern shape can be manufactured.

The method for manufacturing a semiconductor substrate may further include, as necessary, directly or indirectly forming a silicon-containing film on the substrate (this step is hereinafter also referred to as “silicon-containing film formation step”) before the application step (I).

Hereinafter, the composition for forming a resist underlayer film to be used in the method for manufacturing a semiconductor substrate, and the respective steps in the case of including the silicon-containing film formation step, which is an optional step, will be described.

### Composition for Forming a Resist Underlayer Film

The composition for forming a resist underlayer film contains a polymer [A], an acid generating agent [B], and a solvent [C]. The composition may contain any optional component as long as the effect of the present invention is not impaired. The composition for forming a resist underlayer film can form a resist underlayer film superior in pattern rectangularity owing to containing the polymer [A], the acid generating agent [B], and the solvent [C].

### Polymer [A]

The composition may contain one kind or two or more kinds of the polymer [A].

The polymer [A] preferably has a repeating unit represented by formula (1) (this unit is hereinafter also referred to as “repeating unit (1)”).

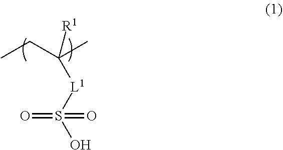

in the formula (1), R¹ is a hydrogen atom or a substituted or unsubstituted monovalent hydrocarbon group having 1 to 20 carbon atoms; and L¹ is a single bond or a divalent linking group.

As used herein, the “hydrocarbon group” includes a chain hydrocarbon group, an alicyclic hydrocarbon group, and an aromatic hydrocarbon group. The “hydrocarbon group” includes a saturated hydrocarbon group and an unsaturated hydrocarbon group. The “chain hydrocarbon group” means a hydrocarbon group that contains no cyclic structure and is composed only of a chain structure, and includes both a linear hydrocarbon group and a branched hydrocarbon group. The “alicyclic hydrocarbon group” means a hydrocarbon group that contains only an alicyclic structure as a ring structure and contains no aromatic ring structure, and includes both a monocyclic alicyclic hydrocarbon group and a polycyclic alicyclic hydrocarbon group (however, the alicyclic hydrocarbon group is not required to be composed of only an alicyclic structure, and may contain a chain structure as a part thereof). The “aromatic hydrocarbon group” means a hydrocarbon group containing an aromatic ring structure as a ring structure (however, the aromatic hydrocarbon group is not required to be composed of only an aromatic ring structure, and may contain an alicyclic structure or a chain structure as a part thereof).

Examples of the monovalent chain hydrocarbon group having 1 to 20 carbon atoms include alkyl groups such as a methyl group, an ethyl group, a n-propyl group, an isopropyl group, a n-butyl group, a sec-butyl group, a tert-butyl group; alkenyl groups such as an ethenyl group, a propenyl group and a butenyl group; and alkynyl groups such as an ethynyl group, a propynyl group and a butynyl group.

Examples of the monovalent alicyclic hydrocarbon group having 3 to 20 carbon atoms include cycloalkyl groups such as a cyclopentyl group and a cyclohexyl group; cycloalkenyl groups such as a cyclopropenyl group, a cyclopentenyl group, and a cyclohexenyl group; bridged cyclic saturated hydrocarbon groups such as a norbornyl group, an adamantyl group, and a tricyclodecyl group; and bridged cyclic unsaturated hydrocarbon groups such as a norbornenyl group and a tricyclodecenyl group.

Examples of the monovalent aromatic hydrocarbon group having 6 to 20 carbon atoms include a phenyl group, a tolyl group, a naphthyl group, an anthracenyl group, and a pyrenyl group.

When R¹ has a substituent, examples of the substituent include monovalent chain hydrocarbon groups having 1 to 10 carbon atoms, halogen atoms such as a fluorine atom, a chlorine atom, a bromine atom, and an iodine atom, alkoxy groups such as a methoxy group, an ethoxy group, and a propoxy group, alkoxycarbonyl groups such as a methoxycarbonyl group and an ethoxycarbonyl group, alkoxycarbonyloxy groups such as a methoxycarbonyloxy group and an ethoxycarbonyloxy group, acyl groups such as a formyl group, an acetyl group, a propionyl group, and a butyryl group, a cyano group, a nitro group, and a hydroxy group.

Among them, a hydrogen atom or a methyl group is preferable as R¹ from the viewpoint of the copolymerizability of a monomer that affords the repeating unit (1).

In the above formula (1), the divalent linking group represented by L¹ is preferably a divalent hydrocarbon group, a carbonyl group, an oxygen atom (—O—), an imino group (—NH—), or a combination thereof.

Examples of the divalent hydrocarbon group as L¹ include a group obtained by removing one hydrogen atom from the monovalent hydrocarbon group having 1 to 20 carbon atoms as R¹.

Among them, a single bond, an alkanediyl group obtained by removing one hydrogen atom from an alkyl group having 1 to 10 carbon atoms, an arylene group obtained by removing one hydrogen atom from a monovalent aromatic hydrocarbon group having 6 to 20 carbon atoms, a carbonyl group, an oxygen atom, an imino group, or a combination thereof is preferable as L 1 , and a single bond, an alkanediyl group having 1 to 5 carbon atoms, a phenylene group, a carbonyl group, an oxygen atom, an imino group, or a combination thereof is more preferable.

Examples of the repeating unit represented by the formula (1) include repeating units represented by formulas (1-1) to (1-10).

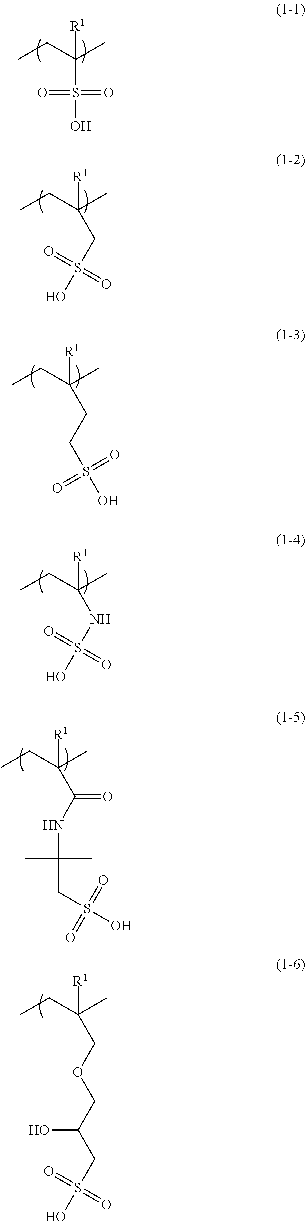

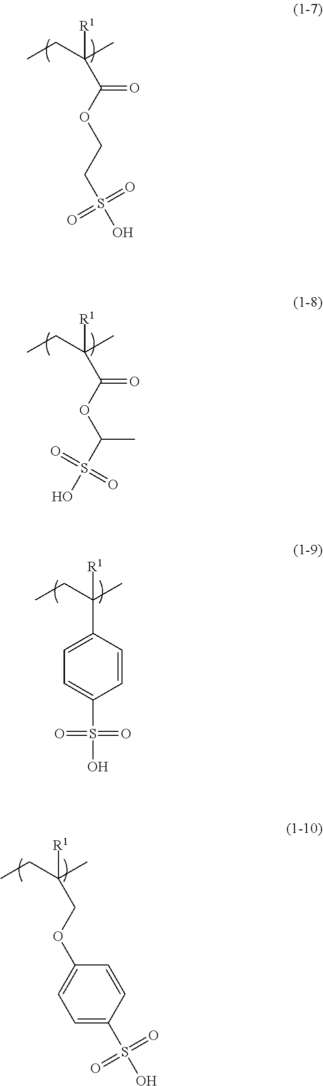

In the above formulas (1-1) to (1-10), R¹ has the same definition as that in the above formula (1). Among them, the repeating units represented by the formulas (1-1), (1-5), and (1-9) are preferable.

The lower limit of the content ratio of the repeating unit (1) containing a sulfonic acid group accounting for among all the repeating units constituting the polymer is preferably 1 mol %, more preferably 5 mol %, still more preferably 10 mol %, and particularly preferably 20 mol %. The upper limit of the content ratio is preferably 100 mol %, more preferably 70 mol %, still more preferably 40 mol %, and particularly preferably 30 mol %. When the content ratio of the repeating unit (1) is set within the above range, pattern rectangularity can be exhibited at a high level. Within the above range, when a basic solution is used as a developer in a step of developing a resist film, a resist underlayer film can be removed together with the resist film.

The polymer [A] preferably has a repeating unit represented by formula (2) (this unit is hereinafter also referred to as “repeating unit (2)”).

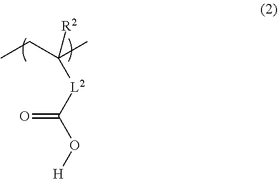

in the formula (2), R² is a hydrogen atom or a substituted or unsubstituted monovalent hydrocarbon group having 1 to 20 carbon atoms; and L² is a single bond or a divalent linking group.

In the formula (2), as the substituted or unsubstituted monovalent hydrocarbon group having 1 to 20 carbon atoms represented by R², a group disclosed as the substituted or unsubstituted monovalent hydrocarbon group having 1 to 20 carbon atoms represented by R¹ in the formula (1) can be suitably employed. A hydrogen atom or a methyl group is preferable as R² from the viewpoint of the copolymerizability of a monomer that affords the repeating unit (2). When R² has a substituent, examples of the substituent suitably include a substituent that can be possessed by R¹ of the above formula (1).

In the formula (2), as the divalent linking group represented by L², the group disclosed as the divalent linking group represented by L¹ in the formula (1) can be suitably employed. As L², a single bond, an alkanediyl group obtained by removing one hydrogen atom from an alkyl group having 1 to 10 carbon atoms, a cycloalkylene group obtained by removing one hydrogen atom from a cycloalkyl group having 5 to 10 carbon atoms, an arylene group obtained by removing one hydrogen atom from a monovalent aromatic hydrocarbon group having 6 to 20 carbon atoms, a carbonyl group, an oxygen atom, or a combination thereof is a preferable, and a single bond, an alkanediyl group having 1 to 5 carbon atoms, a cycloalkylene group having 5 to 7 carbon atoms, a phenylene group, a carbonyl group, an oxygen atom, or a combination thereof is more preferable.

Examples of the repeating unit represented by the formula (2) include repeating units represented by formulas (2-1) to (2-8).

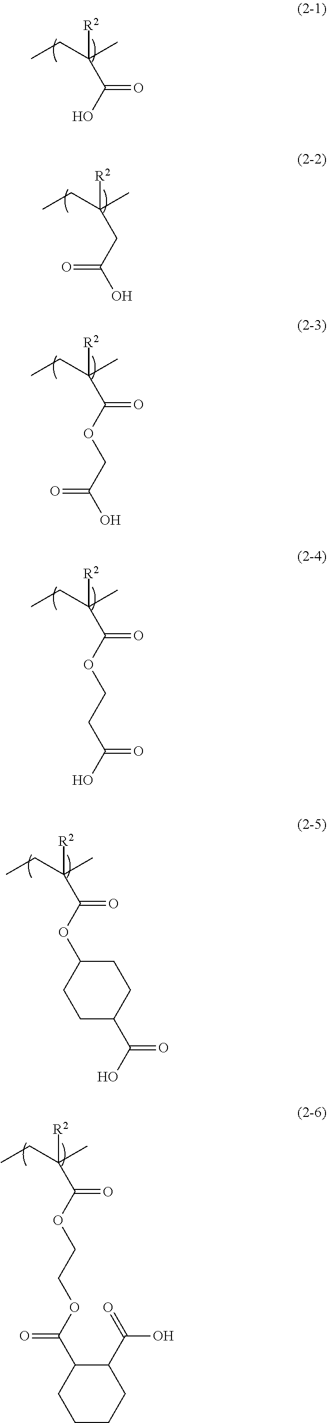

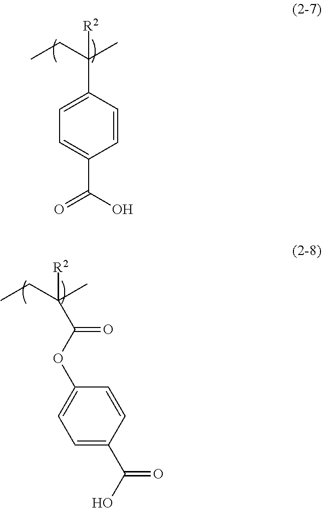

In the above formulas (2-1) to (2-8), R² has the same definition as that in the above formula (2).

When the polymer [A] has the repeating unit (2), the lower limit of the content ratio of the repeating unit (2) accounting for among all the repeating units constituting the polymer [A] is preferably 10 mol %, more preferably 15 mol %, and still more preferably 20 mol %. The upper limit of the content is preferably 99 mol %, more preferably 90 mol %, and still more preferably 80 mol %.

The polymer [A] preferably has a repeating unit represented by formula (3) (excluding the case of being the repeating unit (2)) (this unit is hereinafter also referred to as “repeating unit (3)”).

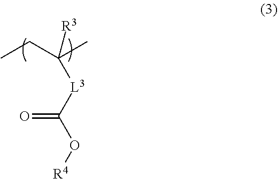

in the formula (3), R³ is a hydrogen atom or a substituted or unsubstituted monovalent hydrocarbon group having 1 to 20 carbon atoms; L³ is a single bond or a divalent linking group; and R⁴ is a substituted or unsubstituted monovalent hydrocarbon group having 1 to 20 carbon atoms.

In the formula (3), as each of the substituted or unsubstituted monovalent hydrocarbon groups having 1 to 20 carbon atoms represented by R³ and R⁴, a group disclosed as the substituted or unsubstituted monovalent hydrocarbon group having 1 to 20 carbon atoms represented by R¹ in the formula (1) can be suitably employed. A hydrogen atom or a methyl group is preferable as R³ from the viewpoint of the copolymerizability of a monomer that affords the repeating unit (3). A monovalent chain hydrocarbon group having 1 to 15 carbon atoms is preferable as R⁴, and a monovalent branched alkyl group having 1 to 10 carbon atoms is more preferable. When R³ or R⁴ has a substituent, examples of the substituent preferably include a substituent that can be possessed by R¹ of the above formula (1).

In the formula (3), as the divalent linking group represented by L³, the group disclosed as the divalent linking group represented by L¹ in the formula (1) can be suitably employed. As L³, a single bond, an alkanediyl group obtained by removing one hydrogen atom from an alkyl group having 1 to 10 carbon atoms, a cycloalkylene group obtained by removing one hydrogen atom from a cycloalkyl group having 5 to 10 carbon atoms, a carbonyl group, an oxygen atom, or a combination thereof is a preferable, a single bond, an alkanediyl group having 1 to 5 carbon atoms, a cycloalkylene group having 5 to 7 carbon atoms, a carbonyl group, an oxygen atom, or a combination thereof is more preferable, and a single bond is still more preferable.

Examples of the repeating unit represented by the formula (3) include repeating units represented by formulas (3-1) to (3-17).

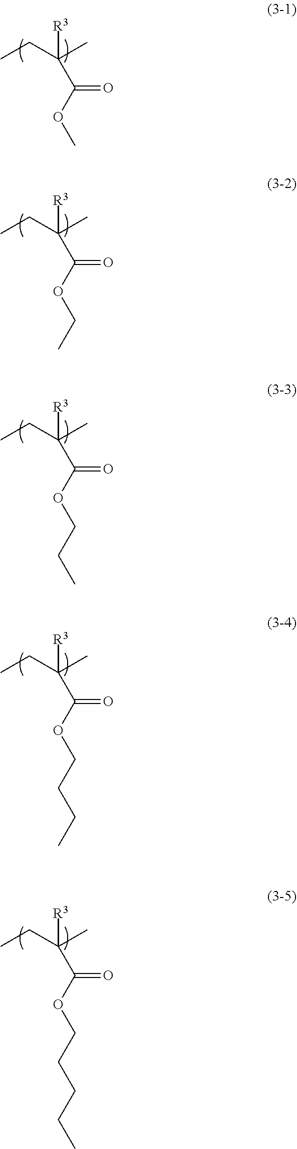

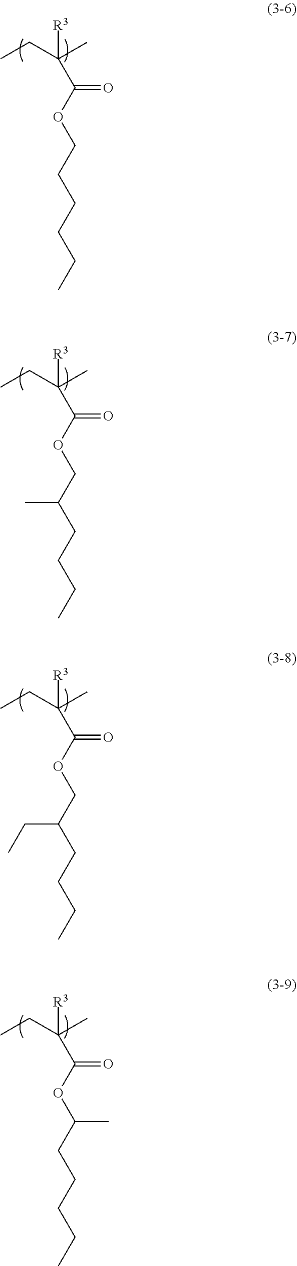

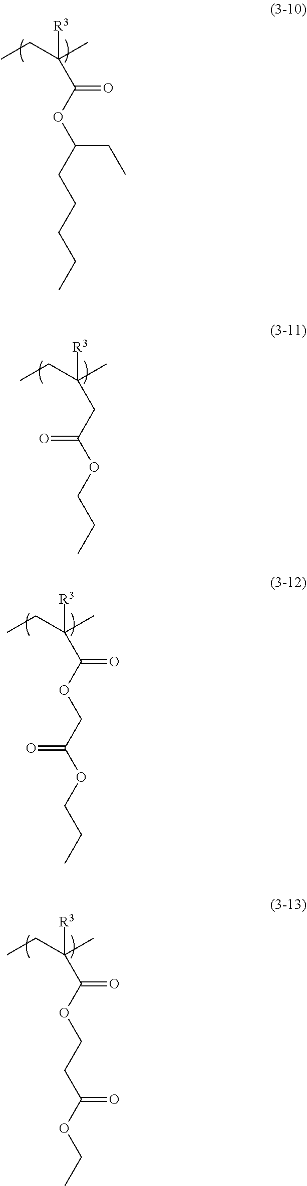

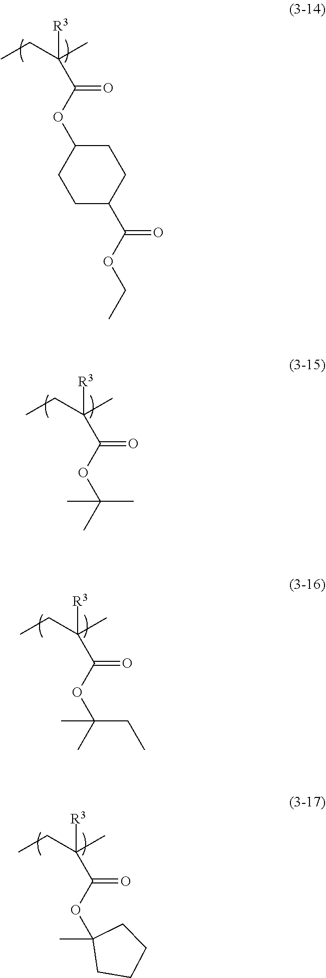

In the formulas (3-1) to (3-17), R³ has the same definition as that in the above formula (3).

When the polymer [A] has the repeating unit (3), the lower limit of the content ratio of the repeating unit (3) accounting for among all the repeating units constituting the polymer [A] is preferably 10 mol %, more preferably 15 mol %, and still more preferably 20 mol %. The upper limit of the content is preferably 90 mol %, more preferably 85 mol %, and still more preferably 80 mol %.

The polymer [A] preferably has a repeating unit represented by formula (4) (excluding the cases of being the repeating units (1), (2), and (3)) (this unit is hereinafter also referred to as “repeating unit (4)”).

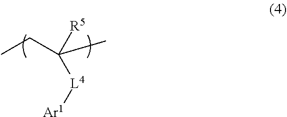

in the formula (4), R⁵ is a hydrogen atom or a substituted or unsubstituted monovalent hydrocarbon group having 1 to 20 carbon atoms; L⁴ is a single bond or a divalent linking group; and Ar¹ is a monovalent group having an aromatic ring having 6 to 20 ring members.

In the present specification, the term “ring members” refers to the number of atoms constituting the ring. For example, a biphenyl ring has 12 ring members, a naphthalene ring has 10 ring members, and a fluorene ring has 13 ring members.

In the formula (4), as the substituted or unsubstituted monovalent hydrocarbon group having 1 to 20 carbon atoms represented by R⁵, a group disclosed as the substituted or unsubstituted monovalent hydrocarbon group having 1 to 20 carbon atoms represented by R¹ in the formula (1) can be suitably employed. A hydrogen atom or a methyl group is preferable as R⁵ from the viewpoint of the copolymerizability of a monomer that affords the repeating unit (4). When R⁵ has a substituent, examples of the substituent suitably include a substituent that can be possessed by R¹ of the above formula (1).

In the formula (4), as the divalent linking group represented by L⁴, the group disclosed as the divalent linking group represented by L¹ in the formula (1) can be suitably employed. As L⁴, a single bond, an alkanediyl group obtained by removing one hydrogen atom from an alkyl group having 1 to 10 carbon atoms, a cycloalkylene group obtained by removing one hydrogen atom from a cycloalkyl group having 5 to 10 carbon atoms, a carbonyl group, an oxygen atom, or a combination thereof is a preferable, a single bond, an alkanediyl group having 1 to 5 carbon atoms, a cycloalkylene group having 5 to 7 carbon atoms, a carbonyl group, an oxygen atom, or a combination thereof is more preferable, and a single bond is still more preferable.

In the above formula (4), examples of the aromatic ring having 6 to 20 ring numbers as Ar¹ include aromatic hydrocarbon rings such as a benzene ring, a naphthalene ring, an anthracene ring, an indene ring, and a pyrene ring, aromatic heterocyclic rings such as a pyridine ring, a pyrazine ring, a pyrimidine ring, a pyridazine ring, and a triazine ring, or a combination thereof. The aromatic ring of the Ar¹ is preferably at least one aromatic hydrocarbon ring selected from the group consisting of a benzene ring, a naphthalene ring, an anthracene ring, a phenalene ring, a phenanthrene ring, a pyrene ring, a fluorene ring, a perylene ring, and a coronene ring, and more preferably a benzene ring, a naphthalene ring, or a pyrene ring.

In the formula (4), suitable examples of the monovalent group having an aromatic ring having 6 to 20 ring members represented by Ar¹ include a group obtained by removing one hydrogen atom from the aromatic ring having 6 to 20 ring members in the Ar¹.

In the formula (4), the monovalent group having an aromatic ring having 6 to 20 ring members represented by Ar¹ may have a substituent. As the substituent in that case, substituents disclosed as examples when R¹ in the above formula (1) has a substituent can be suitably employed. A hydroxy group is preferable as the substituent.

Examples of the repeating unit represented by the formula (4) include repeating units represented by formulas (4-1) to (4-10).

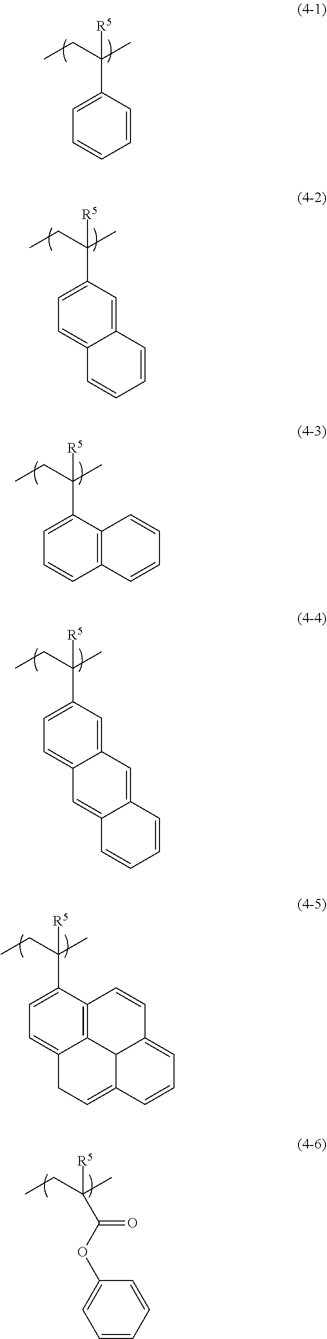

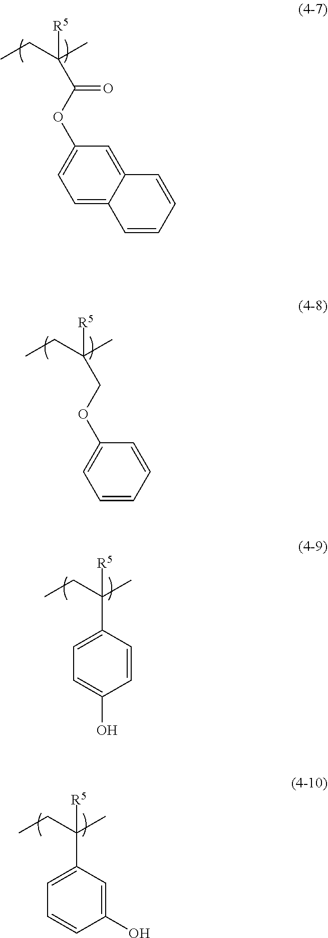

In the formulas (4-1) to (4-10), R⁵ has the same definition as that in the above formula (4). Among them, the repeating units represented by the formulas (4-1), (4-9), and (4-10) are preferable.

When the polymer [A] has the repeating unit (4), the lower limit of the content ratio of the repeating unit (4) accounting for among all the repeating units constituting the polymer [A] is preferably 10 mol %, more preferably 20 mol %, and still more preferably 30 mol %. The upper limit of the content is preferably 95 mol %, more preferably 90 mol %, and still more preferably 80 mol %.

Other repeating units include repeating units used in polymers of resist compositions such as a repeating unit in which a structure of an acid generating agent described later is incorporated.

The lower limit of the weight average molecular weight of the polymer [A] is preferably 500, more preferably 1000, still more preferably 1500, and particularly preferably 2000. The upper limit of the molecular weight is preferably 10000, more preferably 9000, still more preferably 8000, and particularly preferably 7000. The weight average molecular weight is measured as described in EXAMPLES.

The lower limit of the content ratio of the polymer [A] in the composition for forming a resist underlayer film is preferably 1% by mass, more preferably 2% by mass, still more preferably 3% by mass, and particularly preferably 4% by mass in the total mass of the polymer [A] and the solvent [C]. The upper limit of the content ratio is preferably 20% by mass, more preferably 15% by mass, still more preferably 12% by mass, and particularly preferably 10% by mass in the total mass of the polymer [A] and the solvent [C].

The lower limit of the content ratio of the polymer [A] accounting for among the components other than the solvent [C] in the composition for forming a resist underlayer film is preferably 1% by mass, more preferably 5% by mass, still more preferably 10% by mass, and particularly preferably 15% by mass. The upper limit of the content ratio is preferably 99% by mass, more preferably 95% by mass, and still more preferably 90% by mass.

### Method for Synthesizing Polymer [A]

The polymer [A] can be synthesized by performing radical polymerization, ion polymerization, polycondensation, polyaddition, addition condensation, or the like depending on the type of the monomer. For example, when the polymer [A] is synthesized by radical polymerization, the polymer can be synthesized by polymerizing monomers which will afford respective structural units using a radical polymerization initiator of the like in an appropriate solvent.

Examples of the radical polymerization initiator include azo radical initiators, such as azobisisobutyronitrile (AIBN), 2,2′-azobis(4-methoxy-2,4-dimethylvaleronitrile), 2,2′-azobis(2-cyclopropylpropionitrile), 2,2′-azobis(2,4-dimethylvaleronitrile) and dimethyl 2,2′-azobisisobutyrate; and peroxide radical initiators, such as benzoyl peroxide, t-butyl hydroperoxide and cumene hydroperoxide. These radical initiators maybe used singly, or two or more of them may be used in combination.

As the solvent to be used for the polymerization, the solvent [C] described later can be suitably employed. The solvents to be used for the polymerization may be used singly, or two or more solvents may be used in combination.

The reaction temperature in the polymerization is usually 40° C. to 150° C., and preferably 50° C. to 120° C. The reaction time is usually 1 hour to 48 hours, and preferably 1 hour to 24 hours.

### Acid Generating Agent [B]

The acid generating agent [B] is a component that generates an acid by the action of heat or light. The acid generating agent [B] may be used singly, or two or more types thereof may be used in combination.

Examples of the acid generating agent [B] include an onium salt compound, an N-sulfonyloxyimide compound, a sulfonimide compound, a halogen-containing compound, and a diazoketone compound.

Examples of the onium salt compound include a sulfonium salt, a tetrahydrothiophenium salt, an iodonium salt, a phosphonium salt, a diazonium salt, and a pyridinium salt.

Examples of the acid generating agent [B] include the compounds described in paragraphs to of JP-A-2009-134088.

As the acid generating agent [B], an acid generating agent represented by formula (c) is preferable. It is considered that owing to the acid generating agent [B] having the following structure, the diffusion length in a resist underlayer film of an acid generated during the pattern exposure step is further appropriately shortened. As a result, a resist underlayer film superior in pattern rectangularity can be formed.

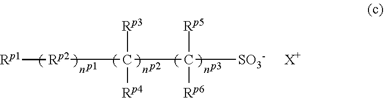

In the formula (c), R^{p1} is a hydrogen atom, a fluorine atom, or a monovalent organic group having 1 to 20 carbon atoms. R^{p2} is a divalent linking group. R^{p3} and R^{p4} are each independently a hydrogen atom, a fluorine atom, a monovalent hydrocarbon group having 1 to 20 carbon atoms, or a monovalent fluorinated hydrocarbon group having 1 to 20 carbon atoms. R^{p5} and R^{p6} are each independently a fluorine atom or a monovalent fluorinated hydrocarbon group having 1 to 20 carbon atoms. n^{p1} is an integer of 0 to 10. n^{p2} is an integer of 0 to 10. n^{p3} is an integer of 1 to 10. When n^{p1} is 2 or more, a plurality of R^{p2}s are identical or different. When n^{p2} is 2 or more, a plurality of R^{p3}s are identical or different, and a plurality of R^{p4}s is identical or different. When n^{p3} is 2 or more, a plurality of R^{p5}s are identical or different, and a plurality of R^{p6}s are identical or different. X⁺ is a monovalent radiation-sensitive onium cation.

Examples of the monovalent organic group having 1 to 20 represented by R^{p1} include a monovalent hydrocarbon group having 1 to 20 carbon atoms, a group (a) containing a divalent heteroatom-containing group between two adjacent carbon atoms of the foregoing hydrocarbon group or at an end located on a bonding side of the foregoing hydrocarbon group, and a group obtained by replacing some or all of the hydrogen atoms of the foregoing hydrocarbon group and the group (a) with a monovalent heteroatom-containing group, or a group obtained by combining them.

Examples of the monovalent hydrocarbon group having 1 to 20 carbon atoms include groups the same as the groups disclosed as examples of the monovalent hydrocarbon group having 1 to 20 carbon atoms represented by R¹ of the above formula (1).

Examples of the divalent heteroatom-containing group include —O—, —CO—, —CO—O—, —S—, —CS—, —SO₂—, —NR′—, and groups in which two or more of the foregoing are combined. R′ is a hydrogen atom or a monovalent hydrocarbon group.

Examples of the monovalent heteroatom-containing group include halogen atoms such as a fluorine atom, a chlorine atom, a bromine atom, and an iodine atom; a hydroxyl group, a carboxyl group, a cyano group, an amino group, and a sulfanyl group (—SH).

R^{p1} preferably contains a ring structure having 6 or more ring members. Examples of the ring structure include an alicyclic structure, an aliphatic heterocyclic structure, an aromatic ring structure, and an aromatic heterocyclic structure each of which has 6 or more ring members.

Examples of the alicyclic structure having 6 or more ring members include:
monocyclic cycloalkane structures such as a cyclohexane structure, a cycloheptane structure, a cyclooctane structure, a cyclononane structure, a cyclodecane structure, and a cyclododecane structure;
monocyclic cycloalkene structures such as a cyclohexene structure, a cycloheptene structure, a cyclooctene structure, and a cyclodecene structure;
polycyclic cycloalkane structures such as a norbornane structure, an adamantane structure, a tricyclodecane structure, and a tetracyclododecane structure; and
polycyclic cycloalkene structures such as a norbornene structure and a tricyclodecene structure.

Examples of the aliphatic heterocyclic structure having 6 or more ring members include:
lactone structures such as a hexanolactone structure and a norbornane lactone structure;
sultone structures such as a hexanosultone structure and a norbornane sultone structure;
oxygen atom-containing heterocyclic structures such as an oxacycloheptane structure and an oxanorbornane structure;
nitrogen atom-containing heterocyclic structures such as an azacyclohexane structure and a diazabicyclooctane structure; and sulfur atom-containing heterocyclic structures such as a thiacyclohexane structure and a thianorbornane structure.

Examples of the aromatic ring structure having 6 or more ring members include a benzene structure, a naphthalene structure, a phenanthrene structure, and an anthracene structure.

Examples of the aromatic heterocyclic structure having 6 or more ring members include oxygen atom-containing heterocyclic structures such as a furan structure, a pyran structure, and a benzopyran structure, and nitrogen atom-containing heterocyclic structures such as a pyridine structure, a pyrimidine structure, and an indole structure.

The lower limit of the number of the ring members of the ring structure of R^{p1} is preferably 7, more preferably 8, still more preferably 9, and particularly preferably 10. The upper limit of the number of the ring members is preferably 15, more preferably 14, still more preferably 13, and particularly preferably 12. When the number of the ring members is set within the above range, the diffusion length of the acid can be further appropriately shortened, and as a result, various types of performance of the chemically amplified resist material described above can be further improved.

Some or all of the hydrogen atoms which the ring structure of R^{p1} has may be replaced with a substituent . As the substituent, the substituents disclosed for the case where R¹ in the above formula (1) has a substituent can be suitably employed. Among them, a hydroxy group is preferable.

Among them, monovalent groups containing an alicyclic structure having 6 or more ring members and monovalent groups containing an aliphatic heterocyclic structure having 6 or more ring members are preferable as R^{p1}, monovalent groups containing an alicyclic structure having 9 or more ring members and monovalent groups containing an aliphatic heterocyclic structure having 9 or more ring members are more preferable, an adamantyl group, a hydroxyadamantyl group, a norbornane lactone-yl group, a norbornane sultone-yl group, and a 5-oxo-4-oxatricyclo [4.3.1.1^{3,8}]undecane-yl group are still more preferable, and an adamantyl group is particularly preferable.

Examples of the divalent linking group represented by R^{p2} include a carbonyl group, an ether group, a carbonyloxy group, a sulfide group, a thiocarbonyl group, a sulfonyl group, a divalent hydrocarbon group, or a combination thereof. As the divalent linking group represented by R^{p2}, a carbonyloxy group, a sulfonyl group, alkanediyl groups, and cycloalkanediyl groups are preferable, a carbonyloxy group and cycloalkanediyl groups are more preferable, a carbonyloxy group and a norbornanediyl group are still more preferable, and a carbonyloxy group is particularly preferable.

Examples of the monovalent hydrocarbon groups having 1 to 20 carbon atoms represented by R^{p3} and R^{p4} include alkyl groups having 1 to 20 carbon atoms. Examples of the monovalent fluorinated hydrocarbon groups having 1 to 20 carbon atoms represented by R^{p3} and R^{p4} include fluorinated alkyl groups having 1 to 20 carbon atoms. As R^{p3} and R^{p4}, a hydrogen atom, a fluorine atom, and fluorinated alkyl groups are preferable, a fluorine atom and perfluoroalkyl groups are more preferable, and a fluorine atom and a trifluoromethyl group are still more preferable.

Examples of the monovalent fluorinated hydrocarbon groups having 1 to 20 carbon atoms represented by R^{p5} and R^{p6} include fluorinated alkyl groups having 1 to 20 carbon atoms. As R^{p5} and R^{p6}, a fluorine atom and fluorinated alkyl groups are preferable, a fluorine atom and perfluoroalkyl groups are more preferable, a fluorine atom and a trifluoromethyl group are still more preferable, and a fluorine atom is particularly preferable.

As n^{p1}, integers of 0 to 5 are preferable, integers of 0 to 3 are more preferable, integers of 0 to 2 are still more preferable, and 0 and 1 are particularly preferable.

As n^{p2}, integers of 0 to 5 are preferable, integers of 0 to 2 are more preferable, integers of 0 and 1 are still more preferable, and 0 is particularly preferable.

As n^{p3}, integers of 1 to 5 are preferable, integers of 1 to 4 are more preferable, integers of 1 to 3 are still more preferable, and 1 and 2 are particularly preferable.

The monovalent radiation-sensitive onium cation represented by X⁺ is a cation that is decomposed by irradiation with exposure light. In an exposure section, a sulfonic acid is generated from a proton generated through the decomposition of the photolyzable onium cation and a sulfonate anion. Examples of the monovalent radiation-sensitive onium cation represented by X⁺ include a cation represented by formula (c-a) (hereinafter, also referred to as “cation (c-a)”), a cation represented by formula (c-b) (hereinafter, also referred to as “cation (c-b)”), and a cation represented by formula (c-c) (hereinafter, also referred to as “cation (c-c)”).

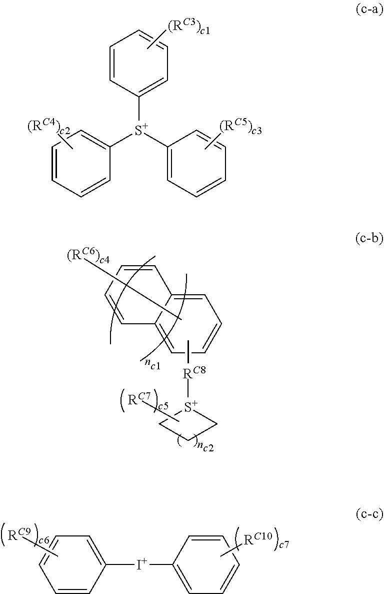

In the formula (c-a), R^{C3}, R^{C4} and R^{C5} each independently represent a substituted or unsubstituted linear or branched alkyl group having 1 to 12 carbon atoms, a substituted or unsubstituted aromatic hydrocarbon group having 6 to 12 carbon atoms, —OSO₂—R^{CC1} or —SO₂—R^{CC2}, or a ring structure constituted by combining two or more of these groups with each other. R^{CC1} and R^{CC2} are each independently a substituted or unsubstituted linear or branched alkyl group having 1 to 12 carbon atoms, a substituted or unsubstituted alicyclic hydrocarbon group having 5 to 25 carbon atoms, or a substituted or unsubstituted aromatic hydrocarbon group having 6 to 12 carbon atoms. c1, c2, and c3 are each independently an integer of 0 to 5. When there are pluralities of R^{C3}s to R^{C5}s, R^{CC1}s and R^{CC2}s, the pluralities of R^{C3}s to R^{C5}s, R^{CC1}s and R^{CC2}s each may be identical or different.

In the above formula (c-b), R^{C6} is a substituted or unsubstituted linear or branched alkyl group having 1 to 8 carbon atoms or a substituted or unsubstituted aromatic hydrocarbon group having 6 to 8 carbon atoms. c4 is an integer of 0 to 7. When there are a plurality of R^{C6}s, the plurality of R^{C6}s may be identical or different, and the plurality of R^{C6} may represent a ring structure constituted by combining them with each other. R^{C7} is a substituted or unsubstituted linear or branched alkyl group having 1 to 7 carbon atoms or a substituted or unsubstituted aromatic hydrocarbon group having 6 or 7 carbon atoms. c5 is an integer of 0 to 6. When there are a plurality of R^{C7}s, the plurality of R^{C7}s may be identical or different, and the plurality of R^{C7}s may represent a ring structure constituted by combining them with each other. n_{C2} is an integer of 0 to 3. R^{C8} is a single bond or a divalent organic group having 1 to 20 carbon atoms. n_{C1} is an integer of 0 to 2.

In the formula (c-c), R^{C9} and R^{C10} each independently represent a substituted or unsubstituted linear or branched alkyl group having 1 to 12 carbon atoms, a substituted or unsubstituted aromatic hydrocarbon group having 6 to 12 carbon atoms, —OSO₂—R^{CC3} or —SO₂—R^{CC4}, or a ring structure constituted by combining two or more of these groups with each other. R^{CC3} and R^{CC4} are each independently a substituted or unsubstituted linear or branched alkyl group having 1 to 12 carbon atoms, a substituted or unsubstituted alicyclic hydrocarbon group having 5 to 25 carbon atoms, or a substituted or unsubstituted aromatic hydrocarbon group having 6 to 12 carbon atoms. c6 and c7 are each independently an integer of 0 to 5. When there are pluralities of R^{C9}s, R^{C10}s, R^{CC3}s and R^{CC4}s, the pluralities of R^{C9}s, R^{C10}S, R^{CC3}s and R^{CC4}s each may be identical or different.

Examples of the unsubstituted linear alkyl groups represented by R^{C3}, R^{C4}, R^{C5}, R^{C6}, R^{C7}, R^{C9}, and R^{C10} include a methyl group, an ethyl group, a n-propyl group, and a n-butyl group.

Examples of the unsubstituted linear alkyl groups represented by R^{C3}, R^{C4}, R^{C5}, R^{C6}, R^{C7}, R^{C9}, and R^{C10} include an isopropyl group, an isobutyl group, a sec-butyl group, and a t-butyl group.

Examples of the unsubstituted aromatic hydrocarbon groups represented by R^{C3}, R^{C4}, R^{C5}, R^{C9}, and R^{C10} include:
aryl groups such as a phenyl group, a tolyl group, a xylyl group, a mesityl group, and a naphthyl group; and
aralkyl groups such as a benzyl group and a phenethyl group.

Examples of the unsubstituted aromatic hydrocarbon groups represented by R^{C6} and R^{C7} include a phenyl group, a tolyl group, and a benzyl group.

As the divalent organic group represented by R^{C8}, a group obtained by removing one hydrogen atom from the monovalent organic group having 1 to 20 carbon atoms represented by R^{p1} can be suitably employed.

As the substituent which may replace hydrogen atoms of an alkyl group and an aromatic hydrocarbon group, the substituents disclosed for the case where R¹ in the above formula (1) has a substituent can be suitably employed. Among them, halogen atoms are preferable, and a fluorine atom is more preferable.

As R^{C3}, R^{C4}, R^{C5}, R^{C6}, R^{C7}, R^{C9}, and R^{C10} unsubstituted linear or branched alkyl groups, fluorinated alkyl groups, unsubstituted monovalent aromatic hydrocarbon groups, —OSO₂—R^{BB6}, and —SO₂—R^{BB5} are preferable, fluorinated alkyl groups and unsubstituted monovalent aromatic hydrocarbon groups are more preferable, and fluorinated alkyl groups are still more preferable. R^{BB5} is an unsubstituted monovalent alicyclic hydrocarbon group or an unsubstituted monovalent aromatic hydrocarbon group.

As c1, c2, and c3 in the formula (c-a), integers of 0 to 2 are preferable, 0 and 1 are more preferable, and 0 is still more preferable. As c4 in the formula (c-b), integers of 0 to 2 are preferable, 0 and 1 are more preferable, and 1 is still more preferable. As c5, integers of 0 to 2 are preferable, 0 and 1 are more preferable, and 0 is still more preferable. As n_{c2}, 2 and 3 are preferable, and 2 is more preferable. As n_{c1}, 0 and 1 are preferable, and 0 is more preferable. As c6 and c7 in the formula (c-c), integers of 0 to 2 are preferable, 0 and 1 are more preferable, and 0 is still more preferable.

Among them, the cation (c-a) and the cation (c-b) are preferable as X⁺, and a diphenyliodonium cation, a triphenylsulfonium cation, a 1-[2-(4-cyclohexylphenylcarbonyl)propan-2-yl]tetrahydrothiophenium cation, and a 4-cyclohexylsulfonylphenyldiphenylsulfonium cation are more preferable.

Examples of the acid generating agent represented by the formula (c) include the compounds represented by formulas (c1) to (c16) (hereinafter also referred to as “compounds (c1) to (c16)”).

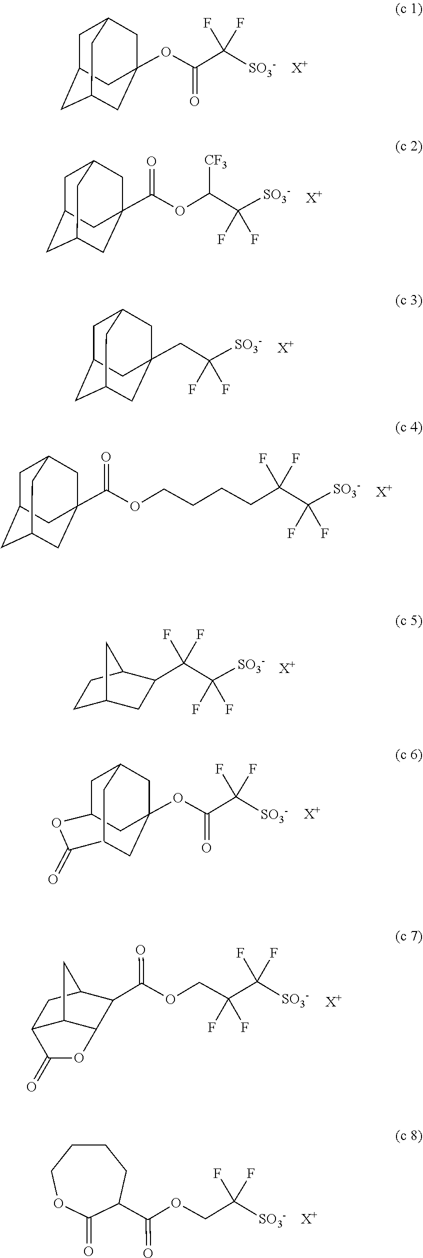

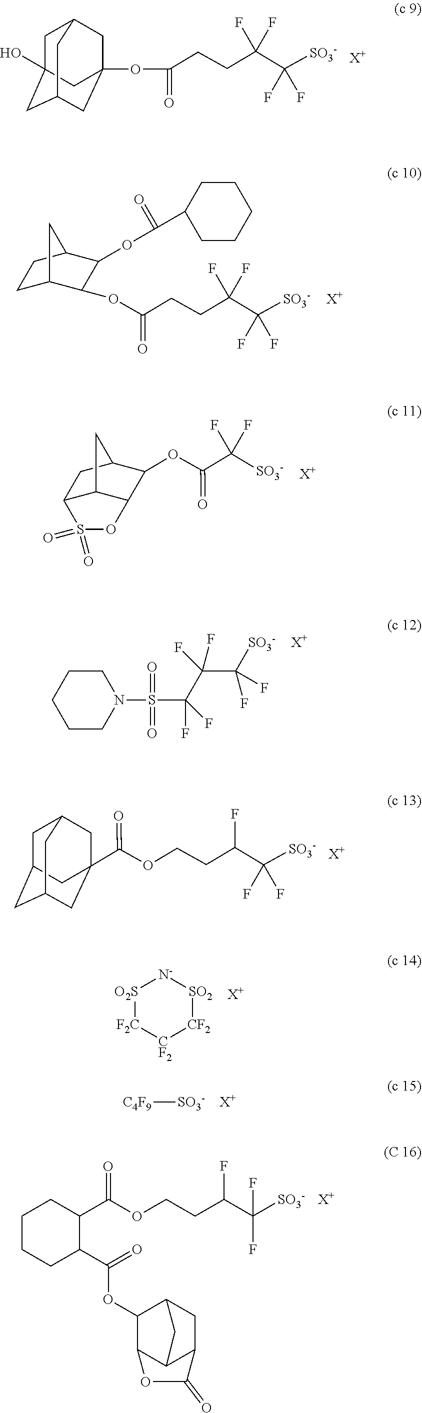

In the above formulas (c1) to (c16), X⁺ represents a monovalent radiation-sensitive onium cation.

As the acid generating agent [B], onium salt compounds are preferable, a sulfonium salt compound and an iodonium salt are more preferable, and the compounds (c5), (c14), (c15) and (c16) and the compounds of Examples are still more preferable.

When the composition for forming a resist underlayer film contains an acid generating agent [B], the lower limit of the content of the acid generating agent[B] is preferably 0.1 parts by mass, more preferably 1 part by mass, and still more preferably 3 parts by mass per 100 parts by mass of the polymer [A]. The upper limit of the content is preferably 40 parts by mass, more preferably 30 parts by mass, and still more preferably 20 parts by mass.

### Solvent [C]

The solvent [C] is not particularly limited as long as it can dissolve or disperse the compound [A], the acid generating agent [B], and optional components contained as necessary.

Examples of the solvent [C] include a hydrocarbon-based solvent, an ester-based solvent, an alcohol-based solvent, a ketone-based solvent, an ether-based solvent, and a nitrogen-containing solvent. The solvent [C] may be used singly or two or more kinds thereof may be used in combination.

Examples of the hydrocarbon-based solvent include aliphatic hydrocarbon-based solvents such as n-pentane, n-hexane, and cyclohexane, and aromatic hydrocarbon-based solvents such as benzene, toluene, and xylene.

Examples of the ester-based solvent include carbonate-based solvents such as diethyl carbonate, acetic acid monoacetate ester-based solvents such as methyl acetate and ethyl acetate, lactone-based solvents such as y-butyrolactone, polyhydric alcohol partial ether carboxylate-based solvents such as diethylene glycol monomethyl ether acetate and propylene glycol monomethyl ether acetate, and lactate ester-based solvents such as methyl lactate and ethyl lactate.

Examples of the alcohol-based solvent include monoalcohol-based solvents such as methanol, ethanol, and n-propanol, 4-methyl-2-pentanol, and polyhydric alcohol-based solvents such as ethylene glycol and 1,2-propylene glycol.

Examples of the ketone-based solvent include chain ketone-based solvents such as methyl ethyl ketone and methyl isobutyl ketone, 2-heptanone, and cyclic ketone-based solvents such as cyclohexanone.

Examples of the ether-based solvent include chain ether-based solvents such as n-butyl ether, cyclic ether-based solvents such as tetrahydrofuran, polyhydric alcohol ether-based solvents such as propylene glycol dimethyl ether, and polyhydric alcohol partial ether-based solvents such as diethylene glycol monomethyl ether, propylene glycol monomethyl ether.

Examples of the nitrogen-containing solvent include chain nitrogen-containing solvents such as N,N-dimethylacetamide, and cyclic nitrogen-containing solvents such as N-methylpyrrolidone.

As the solvent [C], an alcohol-based solvent, an ether-based solvent, or an ester-based solvent is preferable, a monoalcohol-based solvent, a polyhydric alcohol partial ether-based solvent, or a polyhydric alcohol partial ether carboxylate-based solvent is more preferable, and 4-methyl-2-pentanol, propylene glycol monomethyl ether, or propylene glycol monomethyl ether acetate is still more preferable.

The lower limit of the content ratio of the solvent [C] in the composition for forming a resist underlayer film is preferably 50% by mass, more preferably 60% by mass, and still more preferably 70% by mass. The upper limit of the content ratio is preferably 99.9% by mass, more preferably 99% by mass, and still more preferably 95% by mass.

### Optional Component

The composition for forming a resist underlayer film may include an optional component as long as the effect of the composition is not impaired. Examples of the optional component include a crosslinking agent, an acid diffusion controlling agent, and a surfactant. The optional component maybe used singly or two or more kinds thereof may be used in combination.

### Acid Diffusion Controlling Agent [E]

The acid diffusion controlling agent [E] captures an acid and a cation. The acid diffusion controlling agent [E] maybe used singly, or two or more types thereof may be used in combination.

Acid diffusion controlling agents [E] are classified into compounds having radiation reactivity and compounds having no radiation reactivity.

As the compounds having no radiation reactivity, basic compounds are preferable. Examples of the basic compounds include hydroxide compounds, carboxylate compounds, amine compounds, imine compounds, and amide compounds. More specific examples include primary to tertiary aliphatic amines, aromatic amines, heterocyclic amines, nitrogen-containing compounds having a carboxyl group, nitrogen-containing compounds having a sulfonyl group, nitrogen-containing compounds having a hydroxy group, nitrogen-containing compounds having a hydroxyphenyl group, alcoholic nitrogen-containing compounds, nitrogen-containing compounds having a carbamate group, amide compounds, and imide compounds. Among these, nitrogen-containing compounds having a carbamate group are preferable.

Further, the basic compounds maybe Troger's bases; hindered amines such as diazabicycloundecene (DBU) and diazabicyclononene (DBM); and ionic quenchers such as tetrabutylammonium hydroxide (TBAH) and tetrabutylammonium lactate.

Examples of the primary aliphatic amines include ammonia, methylamine, ethylamine, n-propylamine, isopropylamine, n-butylamine, isobutylamine, sec-butylamine, tert-butylamine, pentylamine, tert-amylamine, cyclopentylamine, hexylamine, cyclohexylamine, heptylamine, octylamine, nonylamine, decylamine, dodecylamine, cetylamine, methylenediamine, ethylenediamine, and tetraethylenepentamine.

Examples of the secondary aliphatic amine include dimethylamine, diethylamine, di-n-propylamine, diisopropylamine, di-n-butylamine, diisobutylamine, di-sec-butylamine, dipentylamine, dicyclopentylamine, dihexylamine, dicyclohexylamine, diheptylamine, dioctylamine, dinonylamine, didecylamine, didodecylamine, dicetylamine, N,N-dimethylmethylenediamine, N,N-dimethylethylenediamine, and N,N-dimethyltetraethylenepentamine.

Examples of the tertiary aliphatic amine include trimethylamine, triethylamine, tri-n-propylamine, triisopropylamine, tri-n-butylamine, triisobutylamine, tri-sec-butylamine, tripentylamine, tricyclopentylamine, trihexylamine, tricyclohexylamine, triheptylamine, trioctylamine, trinonylamine, tridecylamine, tridodecylamine, tricetylamine, N,N,N′,N′-tetramethylmethylethylenediamine, N,N,N′,N′-tetramethylethylenediamine, and N,N,N′,N′-tetramethyltetraethylenepentamine.

Examples of the aromatic amine and heterocyclic amine include aniline derivatives such as aniline, N-methylaniline, N-ethylaniline, N-propylaniline, N,N-dimethylaniline, 2-methylaniline, 3-methylaniline, 4-methylaniline, ethylaniline, propylaniline, trimethylaniline, 2-nitroaniline, 3-nitroaniline, 4-nitroaniline, 2,4-dinitroaniline, 2,6-dinitroaniline, 3,5-dinitroaniline, and N,N-dimethyltoluidine; diphenyl(p-tolyl)amine; methyldiphenylamine; triphenylamine; phenylenediamine; naphthylamine; diaminonaphthalene; pyrrole derivatives such as pyrrole, 2H-pyrrole, 1-methylpyrrole, 2,4-dimethylpyrrole, 2,5-dimethylpyrrole, and N-methylpyrrole; oxazole derivatives such as oxazole and isoxazole; thiazole derivatives such as thiazole and isothiazole; imidazole derivatives such as imidazole, 4-methylimidazole, and 4-methyl-2-phenylimidazole; pyrazole derivatives; furazan derivatives; pyrroline derivatives such as pyrroline and 2-methyl-1-pyrroline; pyrrolidine derivatives such as pyrrolidine, N-methylpyrrolidine, pyrrolidinone, and N-methylpyrrolidone; imidazoline derivatives; imidazolidine derivatives; pyridine derivatives such as pyridine, methylpyridine, ethylpyridine, propylpyridine, butylpyridine, 4-(1-butylpentyl)pyridine, dimethylpyridine, trimethylpyridine, triethylpyridine, phenylpyridine, 3-methyl-2-phenylpyridine, 4-tert-butylpyridine, diphenylpyridine, benzylpyridine, methoxypyridine, butoxypyridine, dimethoxypyridine, 4-pyrrolidinopyridine, 2-(1-ethylpropyl)pyridine, aminopyridine, and dimethylaminopyridine; pyridazine derivatives; pyrimidine derivatives; pyrazine derivatives; pyrazoline derivatives; pyrazolidine derivatives; piperidine derivatives; piperazine derivatives; morpholine derivatives; indole derivatives; isoindole derivatives; 1H-indazole derivatives; indoline derivatives; quinoline derivatives such as quinoline and 3-quinolinecarbonitrile; isoquinoline derivatives; cinnoline derivatives; quinazoline derivatives; quinoxaline derivatives; phthalazine derivatives; purine derivatives; pteridine derivatives; carbazole derivatives; phenanthridine derivatives; acridine derivatives; phenazine derivatives; 1,10-phenanthroline derivatives; adenine derivatives; adenosine derivatives; guanine derivatives; guanosine derivatives; uracil derivatives; and uridine derivatives.

Examples of the nitrogen-containing compound having a carboxy group include aminobenzoic acid; indolecarboxylic acid; and amino acid derivatives such as nicotinic acid, alanine, arginine, aspartic acid, glutamic acid, glycine, histidine, isoleucine, glycylleucine, leucine, methionine, phenylalanine, threonine, lysine, 3-aminopyrazine-2-carboxylic acid, and methoxyalanine.

Examples of the nitrogen-containing compound having a sulfonyl group include 3-pyridinesulfonic acid and pyridinium p-toluenesulfonate.

Examples of the nitrogen-containing compound having a hydroxy group, the nitrogen-containing compound having a hydroxyphenyl group, and the alcoholic nitrogen-containing compound include 2-hydroxypyridine, aminocresol, 2,4-quinoline diol, 3-indole methanol hydrate, monoethanolamine, diethanolamine, triethanolamine, N-ethyldiethanolamine, N,N-diethylethanolamine, triisopropanolamine, 2,2′-iminodiethanol, 2-aminoethanol, 3-amino-1-propanol, 4-amino-1-butanol, 4-(2-hydroxyethyl)morpholine, 2-(2-hydroxyethyl)pyridine, 1-(2-hydroxyethyl)piperazine, 1-[2-(2-hydroxyethoxy)ethyl]piperazine, piperidineethanol, 1-(2-hydroxyethyl)pyrrolidine, 1-(2-hydroxyethyl)-2-pyrrolidinone, 3-piperidino-1,2-propanediol, 3-pyrrolidino-1,2-propanediol, 8-hydroxyjulolidine, 3-quinuclidinol, 3-tropanol, 1-methyl-2-pyrrolidine ethanol, 1-aziridine ethanol, N-(2-hydroxyethyl)phthalimide, and N-(2-hydroxyethyl)isonicotinamide.

Examples of the nitrogen-containing compound having a carbamate group include N-(tert-butoxycarbonyl)-L-alanine, N-(tert-butoxycarbonyl)-L-alanine methyl ester, (S)-(−)-2-(tert-butoxycarbonylamino)-3-cyclohexyl-1-propanol, (R)-(+)-2-(tert-butoxycarbonylamino)-3-methyl-1-butanol, (R)-(+)-2-(tert-butoxycarbonylamino)-3-phenylpropanol, 10 (S)-(−)-2-(tert-butoxycarbonylamino)-3-phenylpropanol,

(R)-(+)-2-(tert-butoxycarbonylamino)-3-phenyl-1-propanol, (S)-(−)-2-(tert-butoxycarbonylamino)-3-phenyl-1-propanol, (R)-(+)-2-(tert-butoxycarbonylamino)-1-propanol, (S)-(−)-2-(tert-butoxycarbonylamino)-1-propanol, N-(tert-butoxycarbonyl)-L-aspartic acid 4-benzyl ester, N-(tert-butoxycarbonyl)-O-benzyl-L-threonine, (R)-(+)-1-(tert-butoxycarbonyl)-2-tert-butyl-3-methyl-4-imidazolidinone, (S)-(−)-1-(tert-butoxycarbonyl)-2-tert-butyl-3-methyl-4-imidazolidinone, N-(tert-butoxycarbonyl)-3-cyclohexyl-L-alanine methyl ester, N-(tert-butoxycarbonyl)-L-cysteine methyl ester, N-(tert-butoxycarbonyl)ethanolamine, N-(tert-butoxycarbonyl)ethylenediamine, N-(tert-butoxycarbonyl)-D-glucosamine, Nα-(tert-butoxycarbonyl)-L-glutamine, 1-(tert-butoxycarbonyl)imidazole, N-(tert-butoxycarbonyl)-L-isoleucine, N-(tert-butoxycarbonyl)-L-isoleucine methyl ester, N-(tert-butoxycarbonyl)-L-leucinol, Nα-(tert-butoxycarbonyl)-L-lysine, N-(tert-butoxycarbonyl)-L-methionine, N-(tert-butoxycarbonyl)-3-(2-naphthyl)-L-alanine, N-(tert-butoxycarbonyl)-L-phenylalanine, N-(tert-butoxycarbonyl)-L-phenylalanine methyl ester, N-(tert-butoxycarbonyl)-D-prolinal, N-(tert-butoxycarbonyl)-L-proline, N-(tert-butoxycarbonyl)-L-proline-N′-methoxy-N′-methylamide, N-(tert-butoxycarbonyl)-1H-pyrazole-1-carboxyamidine, (S)-(−)-1-(tert-butoxycarbonyl)-2-pyrrolidinemethanol, (R)-(+)-1-(tert-butoxycarbonyl)-2-pyrrolidinemethanol, 1-(tert-butoxycarbonyl)-3-[4-(1-pyrrolyl)phenyl]-L-alanine, N-(tert-butoxycarbonyl)-L-serine, N-(tert-butoxycarbonyl)-L-serine methyl ester,

N-(tert-butoxycarbonyl)-L-threonine, N-(tert-butoxycarbonyl)-p-toluenesulfonamide, N-(tert-butoxycarbonyl)-S-trityl-L-cysteine, Na-(tert-butoxycarbonyl)-L-tryptophan, N-(tert-butoxycarbonyl)-L-tyrosine, N-(tert-butoxycarbonyl)-L-methyl ester, N-(tert-butoxycarbonyl)-L-valine, N-(tert-butoxycarbonyl)-tyrosine, N-(tert-butoxycarbonyl)-L-valine, N-(tert-butoxycarbonyl)-L-valine methyl ester, N-(tert-butoxycarbonyl)-L-valinol, tert-butyl N-(3-hydroxypropyl)carbamate, tert-butyl N-(6-aminohexyl)carbamate, tert-butyl carbamate, tert-butyl carbazate, tert-butyl N-(benzyloxy)carbamate, tert-butyl 4-benzyl-1-piperazinecarboxylate, tert-butyl (1S,4S)-(−)-2,5-diazabicyclo[2.2.1]heptane-2-carboxylate, tert-butyl N-(2,3-dihydroxypropyl)carbamate, tert-butyl (S)-(−)-4-formyl-2,2-dimethyl-3-oxazolidinecarboxylate, tert-butyl [R-(R*,S*)]-N-[2-hydroxy-2-(3-hydroxyphenyl)-1-methylethyl]carbamate, tert-butyl 4-oxo-1-piperidinecarboxylate, tert-butyl 1-pyrrolecarboxylate, tert-butyl 1-pyrrolidinecarboxylate, and tert-butyl (tetrahydro-2-oxo-3-furanyl)carbamate.

Examples of the amide compound include formamide, N-methylformamide, N,N-dimethylformamide, acetamide, N-methylacetamide, N,N-dimethylacetamide, propionamide, benzamide, and 1-cyclohexylpyrrolidone.

Examples of the imide compound include phthalimide, succinimide, and maleimide.

In addition, the compounds having radiation reactivity are classified into a compound that is degraded by radiation to lose acid diffusion controllability (radiation-degradable compound) and a compound that is generated by radiation to acquire acid diffusion controllability (radiation-generatable compound).

As the radiation-degradable compound, sulfonic acid salts and carboxylic acid salts each containing a radiation-degradable cation are preferred. As the sulfonic acid in the sulfonic acid salt, a weak acid is preferable, and a sulfonic acid that has a hydrocarbon group having 1 to 20 carbon atoms and containing no fluorine is more preferable. Examples of such a sulfonic acid include sulfonic acids such as alkyl sulfonic acids, benzene sulfonic acid, and 10-camphor sulfonic acid. As the carboxylic acid in the carboxylic acid salt, a weak acid is preferable, and a carboxylic acid having 1 to 20 carbon atoms is more preferable. Examples of such a carboxylic acid include carboxylic acids such as formic acid, acetic acid, propionic acid, tartaric acid, succinic acid, cyclohexylcarboxylic acid, benzoic acid, and salicylic acid. As the radiation-degradable cation in the carboxylic acid salt of the radiation-degradable cation, an onium cation is preferable, and examples of the onium cation include an iodonium cation and a sulfonium cation.

As the radiation-generatable compound, a compound that generates a base through exposure to light (radiation-sensitive base generating agent) is preferable, and a nitrogen-containing organic compound that generates an amino group is more preferable.

Examples of the radiation-sensitive base generating agent include the compounds described in JP-A-4-151156, JP-A-4-162040, JP-A-5-197148, JP-A-5-5995, JP-A-6-194834, JP-A-8-146608, JP-A-10-83079, and European patent No. 622682.

Examples of the radiation-sensitive base generating agent include a compound containing a carbamate group (urethane linkage), a compound containing an acyloxyimino group, an ionic compound (anion-cation complex), and a compound containing a carbamoyloxyimino group, and a compound containing a carbamate group (urethane linkage), a compound containing an acyloxyimino group, and an ionic compound (anion-cation complex) are preferable.

Furthermore, as the radiation-sensitive base generating agent, a compound having a ring structure in the molecule is preferable. Examples of the ring structure include benzene, naphthalene, anthracene, xanthone, thioxanthone, anthraquinone, and fluorene.

Examples of the radiation-sensitive base generating agent include 2-nitrobenzylcarbamate, 2,5-dinitrobenzylcyclohexylcarbamate, N-cyclohexyl-4-methylphenylsulfonamide, and 1,1-dimethyl-2-phenylethyl-N-isopropylcarbamate.

When the composition for forming a resist underlayer film contains the acid diffusion controlling agent [E], the lower limit of the content of the acid diffusion controlling agent [E] is preferably 0.1 parts by mass, more preferably 1 part by mass, and still more preferably 3 parts by mass per 100 parts by mass of the polymer [A]. The upper limit of the content is preferably 50 parts by mass, more preferably 40 parts by mass, and still more preferably 30 parts by mass.

### Method for Preparing Composition for Forming Resist Underlayer Film

The composition for forming a resist underlayer film can be prepared by mixing the polymer [A], the acid generating agent [B], the solvent [C] and, as necessary, an optional component in a prescribed ratio and preferably filtering the resulting mixture through a membrane filter having a pore size of 0.5 μm or less, or the like.

### Silicon-Containing Film Forming Step

In this step performed before the application step (I), a silicon-containing film is formed directly or indirectly on a substrate.

Examples of the substrate include metallic or semimetallic substrates such as a silicon substrate, an aluminum substrate, a nickel substrate, a chromium substrate, a molybdenum substrate, a tungsten substrate, a copper substrate, a tantalum substrate, and a titanium substrate. Among them, a silicon substrate is preferred. The substrate may be a substrate having a silicon nitride film, an alumina film, a silicon dioxide film, a tantalum nitride film, or a titanium nitride film formed thereon.

The silicon-containing film can be formed by, for example, application, chemical vapor deposition (CVD), atomic layer deposition (ALD), or the like of a composition for forming a silicon-containing film. Examples of a method for forming a silicon-containing film by application of a composition for forming a silicon-containing film include a method in which a coating film formed by applying a composition for forming a silicon-containing film directly or indirectly to the substrate is cured by exposure and/or heating. As a commercially available product of the composition for forming a silicon-containing film, for example, “NFC SOG01”, “NFC SOG04”, or “NFC SOG080” (all manufactured by JSR Corporation) can be used. By chemical vapor deposition (CVD) or atomic layer deposition (ALD), a silicon oxide film, a silicon nitride film, a silicon oxynitride film, or an amorphous silicon film can be formed.

Examples of the radiation to be used for the exposure include electromagnetic waves such as visible rays, ultraviolet rays, far ultraviolet rays, X-rays, and γ-rays and corpuscular rays such as electron beam, molecular beams, and ion beams.

The lower limit of the temperature in heating the coating film is preferably 90° C., more preferably 150° C., and still more preferably 200° C. The upper limit of the temperature is preferably 550° C., more preferably 450° C., and still more preferably 300° C.

The lower limit of the average thickness of the silicon-containing film is preferably 1 nm, more preferably 10 nm, and still more preferably 20 nm. The upper limit is preferably 20,000 nm, more preferably 1,000 nm, and still more preferably 100 nm. The average thickness of the silicon-containing film can be measured in the same manner as for the average thickness of the resist underlayer film.

Examples of a case where the silicon-containing film is formed indirectly on the substrate include a case where the silicon-containing film is formed on a low dielectric insulating film or an organic underlayer film formed on the substrate.

### Application Step (I)

In this step, a composition for forming a resist underlayer film is applied to the silicon-containing film formed on the substrate. The method of the application of the composition for forming a resist underlayer film is not particularly limited, and the application can be performed by an appropriate method such as spin coating, cast coating, or roll coating. As a result, a coating film is formed, and volatilization of the solvent [C] or the like occurs, so that a resist underlayer film is formed.

When the composition for forming a resist underlayer film is applied directly to the substrate, the silicon-containing film formation step may be omitted.

Next, the coating film formed by the application is heated. The formation of the resist underlayer film is promoted by heating the coating film. More specifically, volatilization or the like of the solvent [C] is promoted by heating the coating film.

The heating of the coating film may be performed either in the air atmosphere or in a nitrogen atmosphere. The lower limit of the heating temperature is preferably 100° C., more preferably 150° C., and still more preferably 200° C. The upper limit of the heating temperature is preferably 400° C., more preferably 350° C., and still more preferably 280° C. The lower limit of the heating time is preferably 15 seconds, and more preferably 30 seconds. The upper limit of the time is preferably 1,200 seconds, and more preferably 600 seconds.

The lower limit of the film thickness (average thickness) of the resist underlayer film to be formed is preferably 0.5 nm, more preferably 1 nm, and still more preferably 2 nm. The upper limit of the average thickness is 6 nm, preferably 5.5 nm, more preferably 5 nm, still more preferably 4.5 nm, and particularly preferably 4 nm. The average thickness is measured as described in Examples.

### Application Step (II)

In this step, a composition for forming a resist film is formed on the resist underlayer film formed by the step of applying a composition for forming a resist underlayer film. The method of applying the composition for forming a resist film is not particularly limited, and examples thereof include a spin coating method.

Describing this step more in detail, for example, a resist composition is applied such that a resist film formed comes to have a prescribed thickness, and then prebaking (hereinafter also referred to as “PB”) is performed to volatilize the solvent in the coating film. As a result, a resist film is formed.

The PB temperature and the PB time may be appropriately determined according to the type and the like of the composition for forming a resist film to be used. The lower limit of the PB temperature is preferably 30° C., and more preferably 50° C. The upper limit of the PB temperature is preferably 200° C., and more preferably 150° C. The lower limit of the PB time is preferably 10 seconds, and more preferably 30 seconds. The upper limit of the PB time is preferably 600 seconds, and more preferably 300 seconds.

Examples of the composition for forming a resist film to be used in this step include a positive or negative chemically amplified resist composition containing a radiation-sensitive acid generating agent, a positive resist composition containing an alkali-soluble resin and a quinonediazide-based photosensitizer, a negative resist composition containing an alkali-soluble resin and a crosslinking agent, and a metal-containing resist composition containing a metal such as tin or zirconium.

### Exposure Step

In this step, a resist film formed in the step of applying a composition for forming a resist film is exposed to radiation.

Radiation to be used for the exposure can be appropriately selected according to the type or the like of the composition for forming a resist film to be used. Examples thereof include electromagnetic rays such as visible rays, ultraviolet rays, far-ultraviolet, X-rays, and y-rays and corpuscular rays such as electron beam, molecular beams, and ion beams. Among these, far-ultraviolet rays are preferable, and KrF excimer laser light (wavelength: 248 nm), ArF excimer laser light (wavelength: 193 nm), F₂ excimer laser light (wavelength: 157 nm), Kr₂ excimer laser light (wavelength: 147 nm), ArKr excimer laser light (wavelength: 134 nm) or extreme ultraviolet rays (wavelength: 13.5 nm, etc., also referred to as “EUV”) are more preferred, and ArF excimer laser light or EUV is even more preferred. Further, the exposure conditions can be determined as appropriate depending on the type of resist film forming composition used.

In this step, post exposure baking (hereinafter, also referred to as “PEB”) can be performed after the exposure in order to improve the resist film performance such as resolution, pattern profile, and developability. The PEB temperature and the PEB time may be appropriately determined according to the type and the like of the composition for forming a resist film to be used. The lower limit of the PEB temperature is preferably 50° C., and more preferably 70° C. The upper limit of the PEB temperature is preferably 200° C., and more preferably 150° C. The lower limit of the PEB time is preferably 10 seconds, and more preferably 30 seconds. The upper limit of the PEB time is preferably 600 seconds, and more preferably 300 seconds.

### Development Step

In this step, the exposed resist film is developed. At this time, a part of the resist underlayer film may also be developed. Examples of the developer to be used for the development include an aqueous alkaline solution (alkaline developer) and an organic solvent-containing solution (organic solvent developer).

The basic solution for the alkali development is not particularly limited, and a publicly known basic solution can be used. Examples of the basic solution for the alkali development include, in the alkaline development, an alkaline aqueous solution obtained by dissolving at least one alkaline compound such as sodium hydroxide, potassium hydroxide, sodium carbonate, sodium silicate, sodium metasilicate, ammonia water, ethylamine, n-propylamine, diethylamine, di-n-propylamine, triethylamine, methyldiethylamine, ethyldimethylamine, triethanolamine, tetramethyl ammonium hydroxide (TMAH), pyrrole, piperidine, choline, 1,8-diazabicyclo-[5.4.0]-7-undecene, and 1,5-diazabicyclo-[4.3.0]-5-nonene. Among them, the aqueous TMAH solution is preferable, and a 2.38% by mass aqueous TMAH solution is more preferable.

Examples of the organic solvent developer in the case of performing organic solvent development include the same as those disclosed as the examples of the solvent [C] described above. As the organic solvent developer, an ester-based solvent, an ether-based solvent, an alcohol-based solvent, a ketone-based solvent and/or a hydrocarbon-based solvent is preferable, a ketone-based solvent is more preferable, and 2-heptanone is particularly preferable.

In this step, washing and/or drying may be performed after the development.

### Etching Step

In this step, etching is performed using the resist pattern (and the resist underlayer film pattern) as a mask. The number of times of the etching may be once. Alternatively, etching may be performed a plurality of times, that is, etching may be sequentially performed using a pattern obtained by etching as a mask. From the viewpoint of obtaining a pattern having a favorable shape, etching is preferably performed a plurality of times. When performed a plurality of times, etching is performed to the silicon-containing film, and the substrate sequentially in order. Examples of an etching method include dry etching and wet etching. Dry etching is preferable from the viewpoint of achieving a favorable shape of the pattern of the substrate. In the dry etching, for example, gas plasma such as oxygen plasma is used. As a result of the etching, a semiconductor substrate having a prescribed pattern is obtained.

The dry etching can be performed using, for example, a publicly known dry etching apparatus. The etching gas used for dry etching can be appropriately selected according to the elemental composition of the film to be etched, and for example, fluorine-based gases such as CHF₃, CF₄, C₂F₆, C₃F₈, and SF₆, chlorine-based gases such as Cl₂ and BCl₃, oxygen-based gases such as O₂, O₃, and H₂O, reducing gases such as H₂, NH₃, CO, CO₂, CH₄, C₂H₂, C₂H₄, C₂H₆, C₃H₄, C₃H₆, C₃H₈, HF, HI, HBr, HCl, NO, and BCl₃, and inert gases such as He, N₂ and Ar are used. These gases can also be mixed and used. When the substrate is etched using the pattern of the resist underlayer film as a mask, a fluorine-based gas is usually used.

When the silicon-containing film remains on the substrate or the like after the substrate pattern formation, the silicon-containing film can be removed by performing a removal step described later.

### Composition for Forming a Resist Underlayer Film

The composition for forming a resist underlayer film contains the polymer [A], the acid generating agent [B], and the solvent [C]. As such a composition for forming a resist underlayer film, the composition for forming a resist underlayer film to be used in the above-described method for manufacturing a semiconductor substrate can be suitably employed.

### EXAMPLES

Hereinbelow, the present invention will specifically be described on the basis of examples, but is not limited to these examples.

### Weight-Average Molecular Weight (Mw)

The Mw of a polymer (x-1) was measured by gel permeation chromatography (detector: differential refractometer) with monodisperse polystyrene standards using GPC columns (“G2000HXL” ×2 and “G3000HXL” ×1) manufactured by Tosoh Corporation under the following analysis conditions: flow rate: 1.0 mL/min; elution solvent: tetrahydrofuran; column temperature: 40° C.

### Average Thickness of Resist Underlayer Film

The average thickness of a resist underlayer film was determined as a value obtained by measuring the film thickness at arbitrary nine points at intervals of 5 cm including the center of the resist underlayer film formed on a silicon wafer using a spectroscopic ellipsometer (“M2000D” available from J. A. WOOLLAM Co.) and calculating the average value of the film thicknesses.

### Synthesis of Polymer [A]

The polymers represented by formulas (A-1) and (A-2) (hereinafter also referred to as “polymers (A-1) and (A-2)”) were each synthesized by the following procedure.

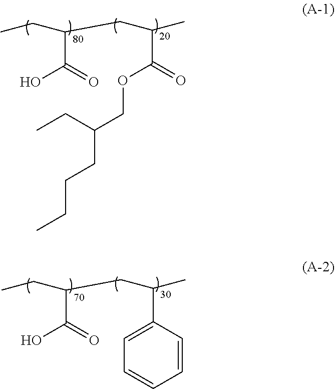

### [Synthesis Example 1-1] (Synthesis of polymer (A-1))

63 g of acrylic acid, 36 g of 2-ethylhexyl acrylate, and 21.2 g of dimethyl 2,2′-azobis(2-methylpropionate) were added to prepare a monomer solution. In a nitrogen atmosphere, 300 g of methyl isobutyl ketone was placed in a reaction vessel and heated to 80° C., and the monomer solution was added dropwise over 3 hours with stirring. A polymerization reaction was performed for 6 hours with the start of the dropwise addition regarded as the start time of the polymerization reaction, and then the resulting mixture was cooled to 30° C. or lower. To the resulting reaction solution was added 300 g of propylene glycol monomethyl ether, and methyl isobutyl ketone was removed by concentration under reduced pressure, affording a propylene glycol monomethyl ether solution of polymer (A-1). The Mw of the polymer (A-1) was 6,500.

### [Synthesis Example 1-2] (Synthesis of Polymer (A-2))

66 g of acrylic acid, 34 g of styrene, and 25.1 g of dimethyl 2,2′-azobis(2-methylpropionate) were added to prepare a monomer solution. In a nitrogen atmosphere, 300 g of methyl isobutyl ketone was placed in a reaction vessel and heated to 80° C., and the monomer solution was added dropwise over 3 hours with stirring. A polymerization reaction was performed for 6 hours with the start of the dropwise addition regarded as the start time of the polymerization reaction, and then the resulting mixture was cooled to 30° C. or lower. To the resulting reaction solution was added 300 g of propylene glycol monomethyl ether, and methyl isobutyl ketone was removed by concentration under reduced pressure, affording a propylene glycol monomethyl ether solution of polymer (A-2). The Mw of the polymer (A-2) was 5,300.

### Preparation of Composition for Forming a Resist Underlayer Film

The polymer [A], the acid generating agent [B], the solvent [C], the crosslinking agent [D], and the acid diffusion controlling agent [E] used for the preparation of a composition for forming a resist underlayer film are shown below.

### Polymer [A]

The polymers (A-1) and (A-2) synthesized above and the following polymer (A-3) (Mw: 8,900)

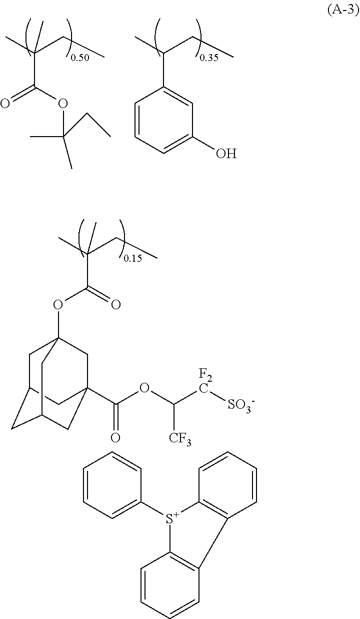

In the above formulas (A-1) to (A-3), the number attached to each structural unit indicates the content ratio (mol %) of the structural unit.

### Acid generating agent [B]

Compounds represented by formulas (B-1) to (B-49).

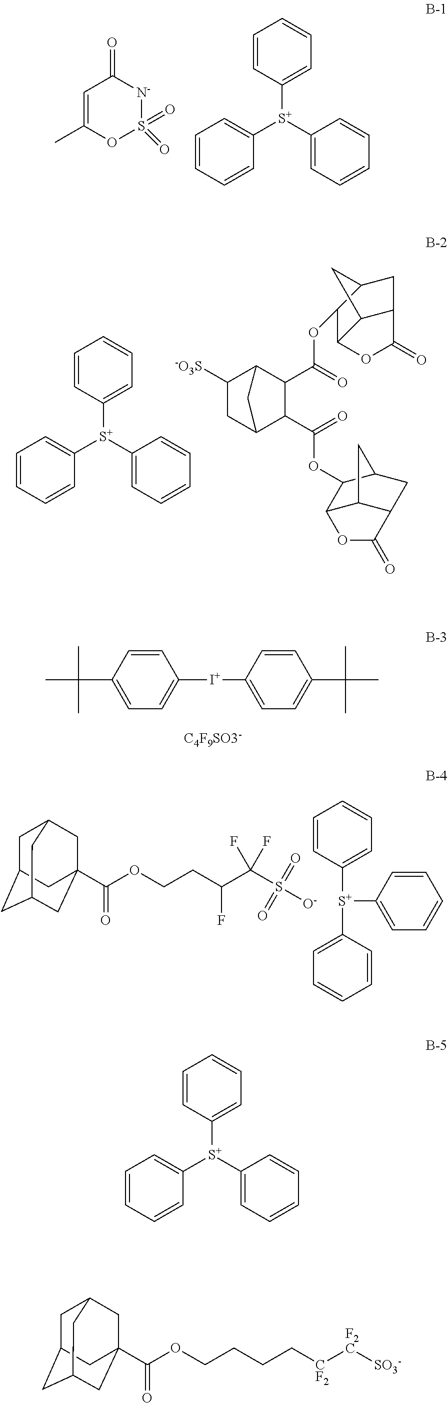

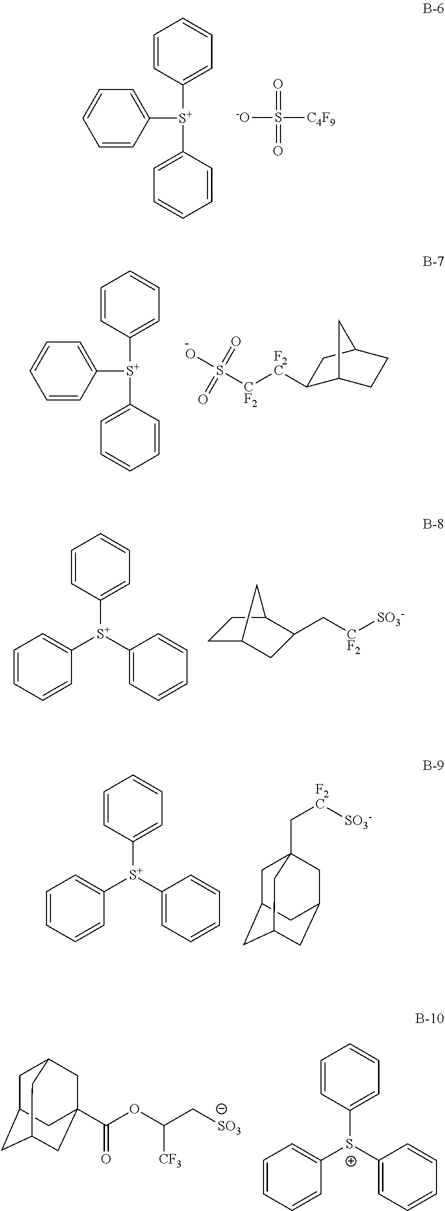

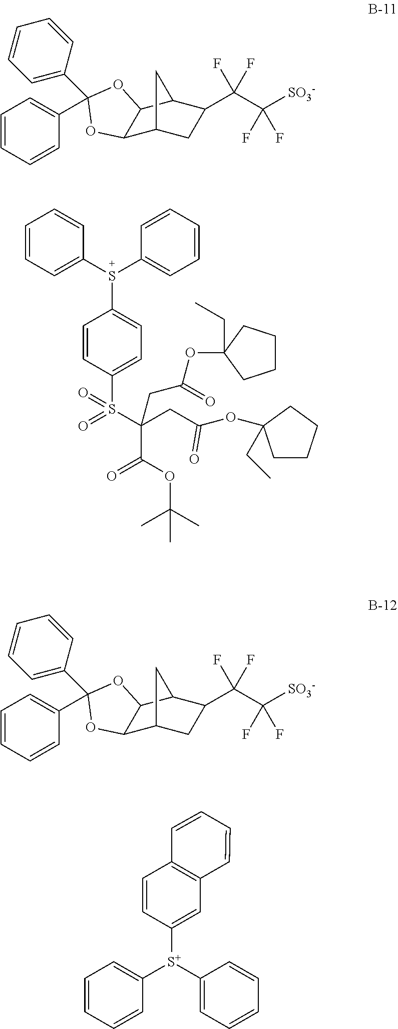

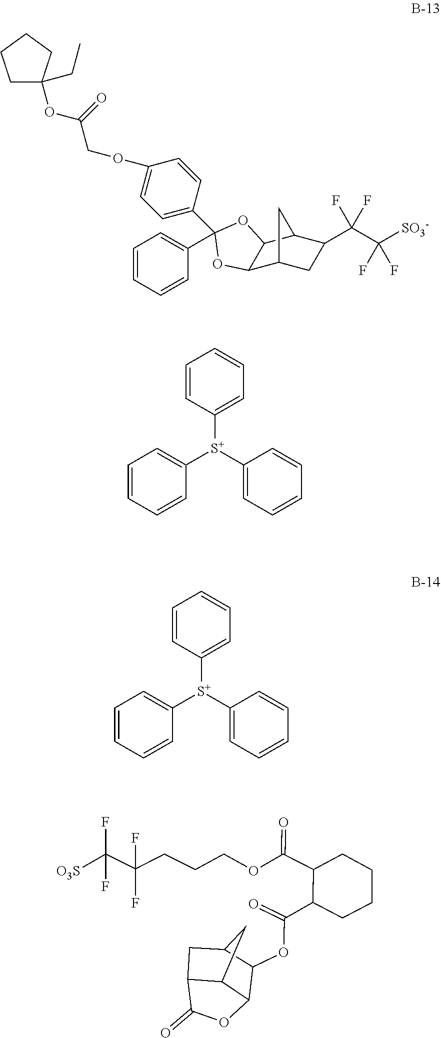

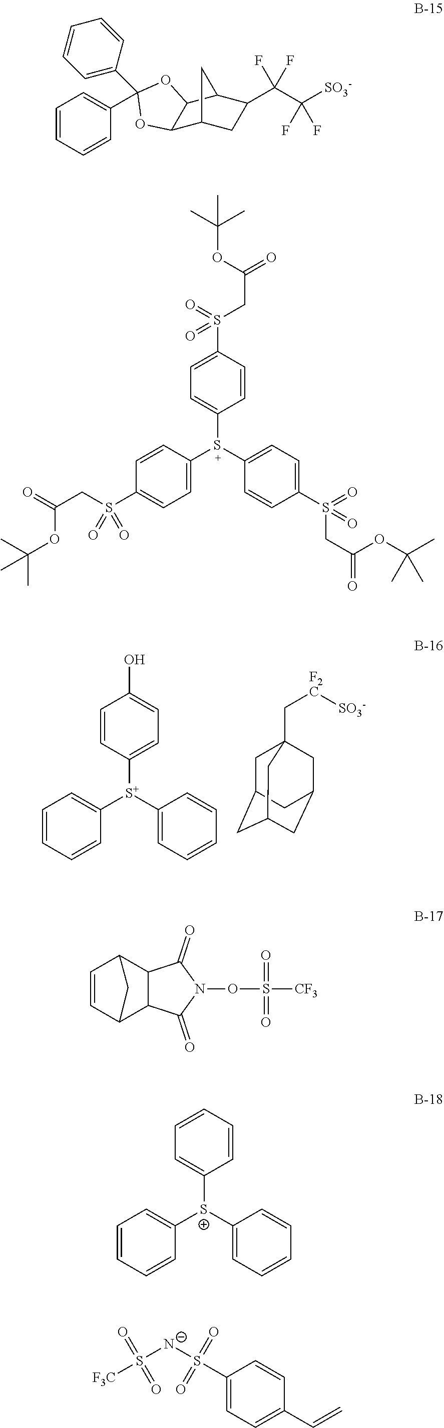

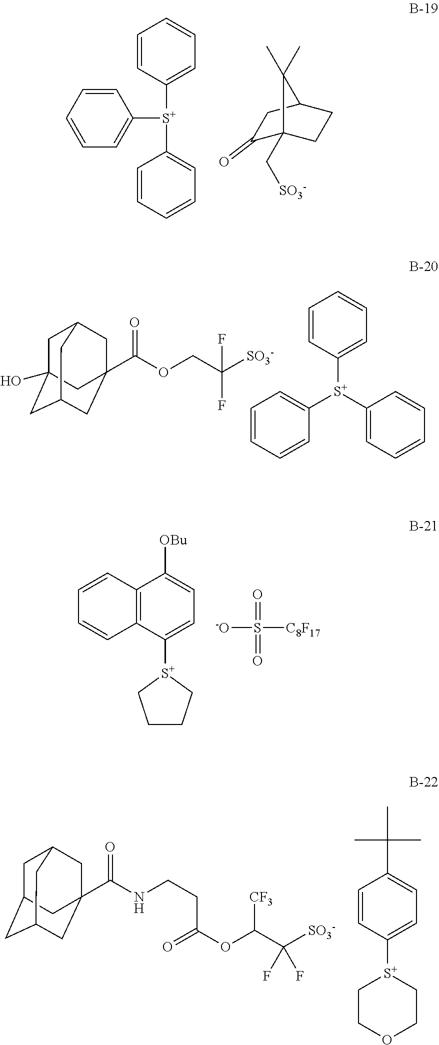

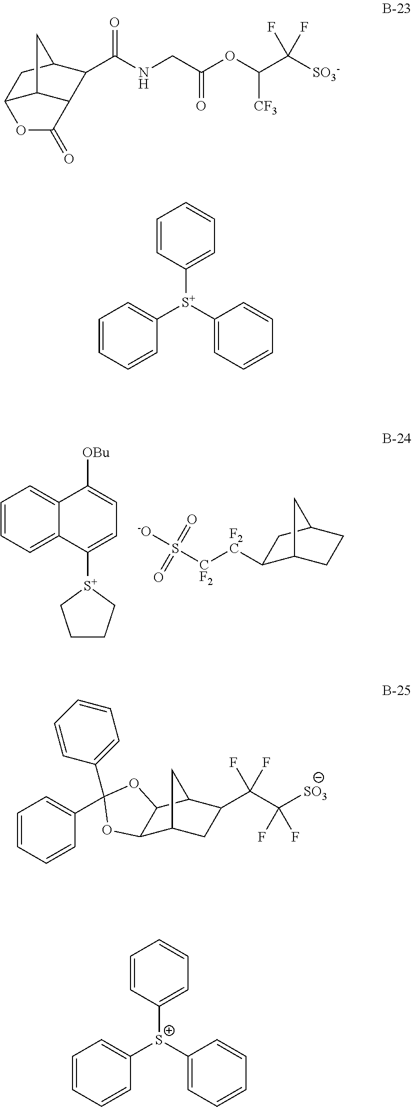

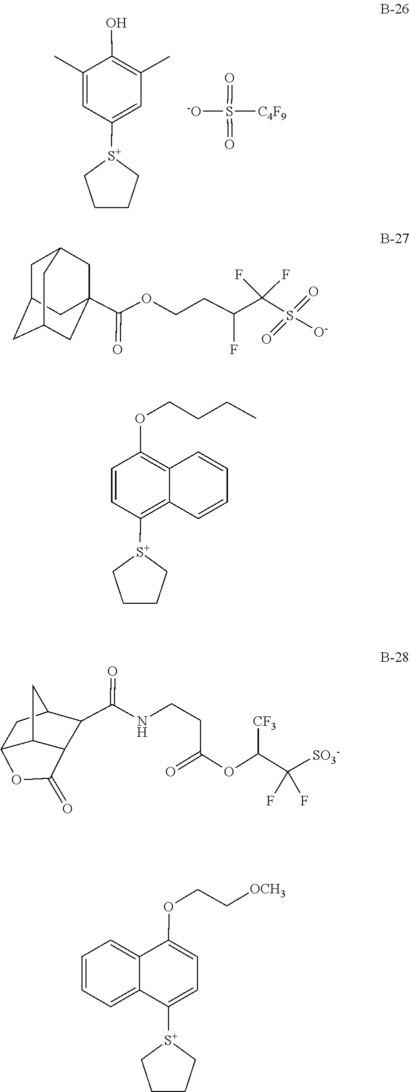

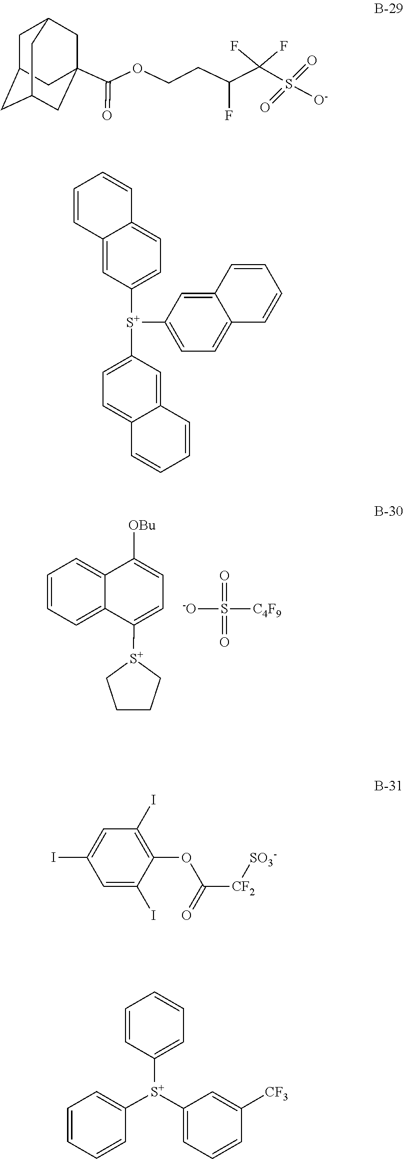

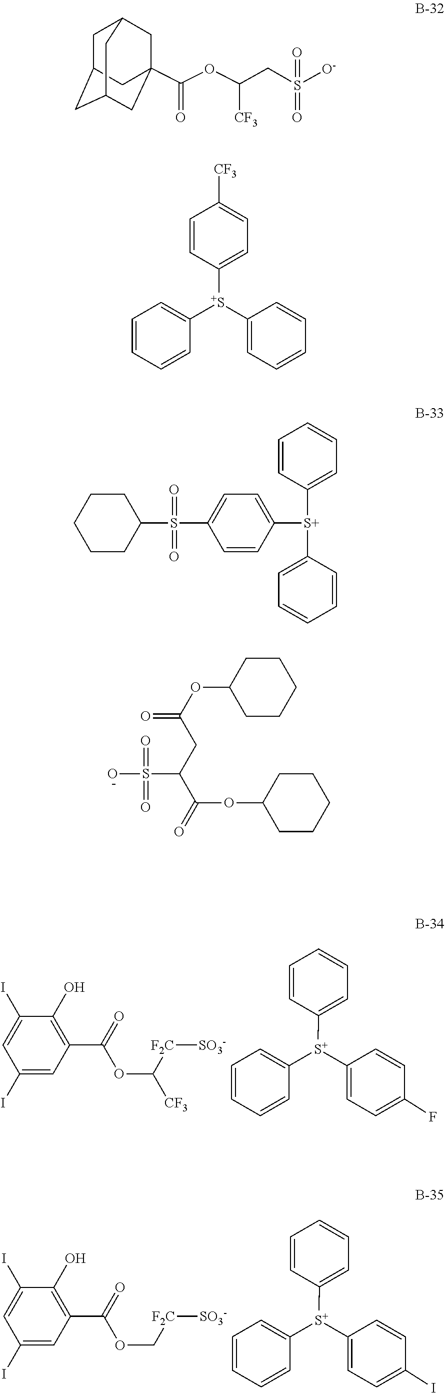

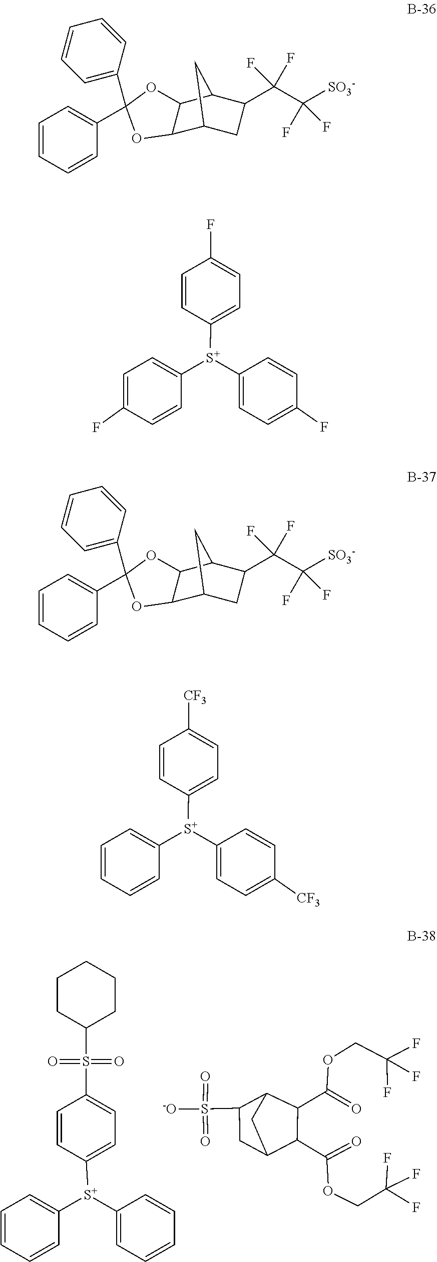

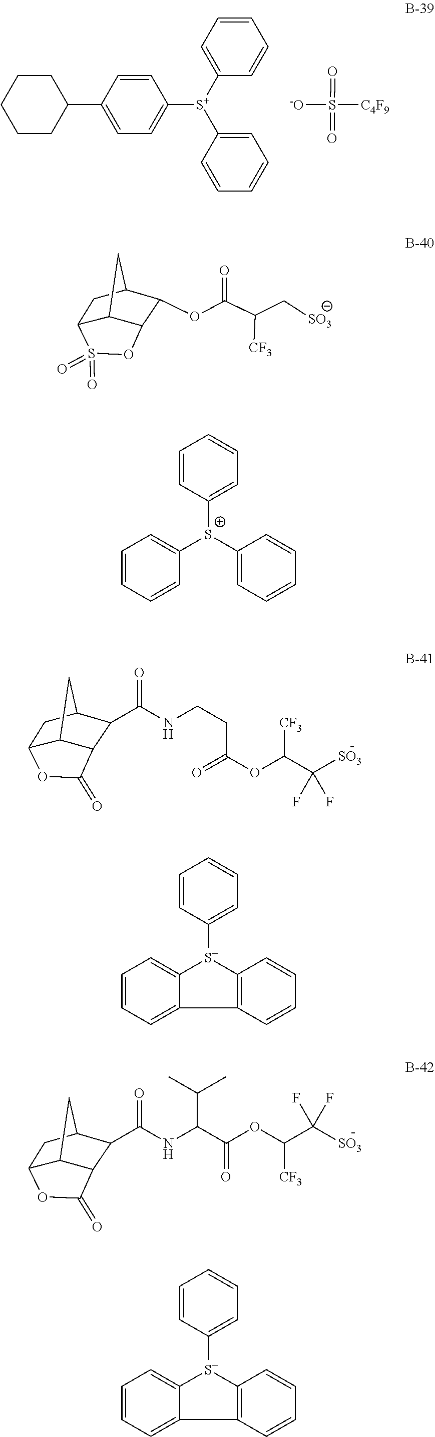

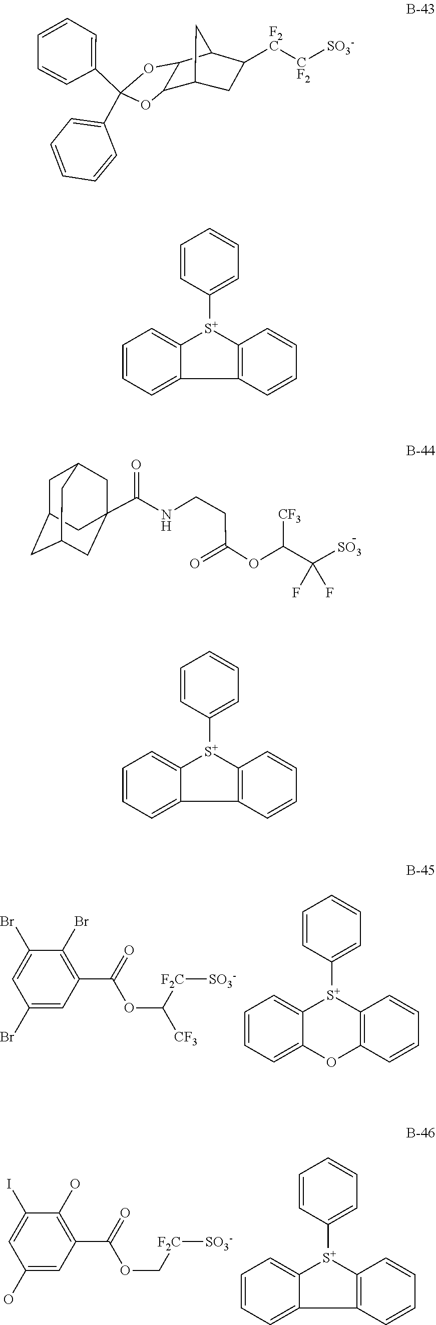

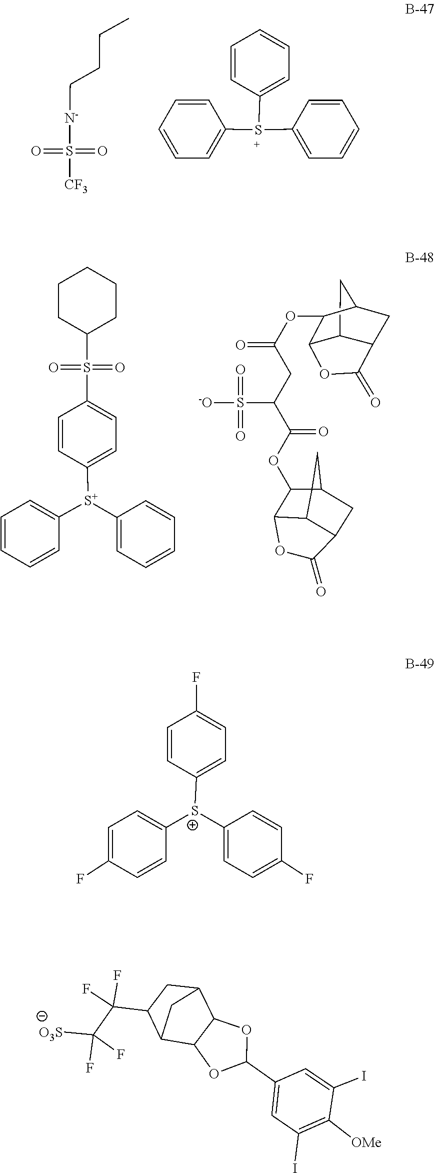

### Solvent [C]

C-1: Propylene glycol monomethyl ether acetate

C-2: Propylene glycol monomethyl ether

### Crosslinking agent [D]

D-1: Compound represented by formula (D-1)

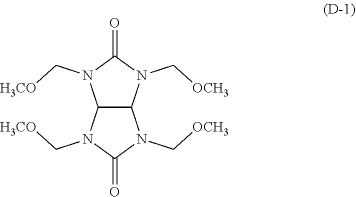 [SMILES: COCN1C(=O)N(COC)C2C1N(COC)C(=O)N2COC]

### Acid diffusion controlling agent [E]

Compounds represented by formulas (E-1) to (E-9)

| | |
|---|---|
| E-1 | 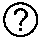 |
| E-2 | 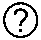 |
| E-3 | 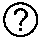 |
| E-4 | 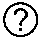 |
| E-5 | 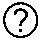 |
| E-6 | 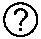 |
| E-7 | 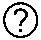 |
| E-8 | 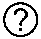 |
| E-9 | 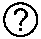 |

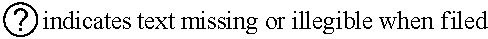

### Example 1-1

50 parts by mass of (A-1) and 50 parts by mass of (A-2) as the polymer [A] and 10 parts by mass of (B-1) as the acid generating agent [B] were dissolved in 1100 parts by mass of (C-1) and 200 parts by mass of (C-2) as the solvent [C] (including the propylene glycol monomethyl ether contained in the propylene glycol monomethyl ether solution of the polymer (A-1)). The resulting solution was filtered through a polytetrafluoroethylene (PTFE) membrane filter having a pore size of 0.45 μm to prepare a composition for forming a resist underlayer film (J-1).

### Examples 1-2 to 1-81 and Comparative Example 1-1

Compositions for forming a resist underlayer film (J-2) to (J-81) and (CJ-1) were prepared in the same manner as in Example 1 except for using the components of the types and contents given in the following Tables 1 and 2. “-” in the column [B] in Table 1 and “-” in the column [E] in Table 2 each indicate that the corresponding component was not used.

TABLE 1

| | | | | Acid generating | | | | Crosslinking | |
|---|---|---|---|---|---|---|---|---|---|
| | | Polymer [A] | | agent [B] | | Solvent [C] | | agent [D] | |
| | Composition for | | Content | | Content | | Content | | Content |
| | forming resist | | (parts by | | (parts by | | (parts by | | (parts by |
| | underlayer film | Type | mass) | Type | mass) | Type | mass) | Type | mass) |
| Example 1-1 | J-1 | A-1/A-2 | 50/50 | B-1 | 10 | C-1/C-2 | 1100/200 | D-1 | 30 |
| Example 1-2 | J-2 | A-1/A-2 | 50/50 | B-2 | 10 | C-1/C-2 | 1100/200 | D-1 | 30 |
| Example 1-3 | J-3 | A-1/A-2 | 50/50 | B-3 | 10 | C-1/C-2 | 1100/200 | D-1 | 30 |
| Example 1-4 | J-4 | A-1/A-2 | 50/50 | B-4 | 10 | C-1/C-2 | 1100/200 | D-1 | 30 |
| Example 1-5 | J-5 | A-1/A-2 | 50/50 | B-5 | 10 | C-1/C-2 | 1100/200 | D-1 | 30 |
| Example 1-6 | J-6 | A-1/A-2 | 50/50 | B-6 | 10 | C-1/C-2 | 1100/200 | D-1 | 30 |
| Example 1-7 | J-7 | A-1/A-2 | 50/50 | B-7 | 10 | C-1/C-2 | 1100/200 | D-1 | 30 |
| Example 1-8 | J-8 | A-1/A-2 | 50/50 | B-8 | 10 | C-1/C-2 | 1100/200 | D-1 | 30 |
| Example 1-9 | J-9 | A-1/A-2 | 50/50 | B-9 | 10 | C-1/C-2 | 1100/200 | D-1 | 30 |
| Example 1-10 | J-10 | A-1/A-2 | 50/50 | B-10 | 10 | C-1/C-2 | 1100/200 | D-1 | 30 |
| Example 1-11 | J-11 | A-1/A-2 | 50/50 | B-11 | 10 | C-1/C-2 | 1100/200 | D-1 | 30 |
| Example 1-12 | J-12 | A-1/A-2 | 50/50 | B-12 | 10 | C-1/C-2 | 1100/200 | D-1 | 30 |
| Example 1-13 | J-13 | A-1/A-2 | 50/50 | B-13 | 10 | C-1/C-2 | 1100/200 | D-1 | 30 |
| Example 1-14 | J-14 | A-1/A-2 | 50/50 | B-14 | 10 | C-1/C-2 | 1100/200 | D-1 | 30 |
| Example 1-15 | J-15 | A-1/A-2 | 50/50 | B-15 | 10 | C-1/C-2 | 1100/200 | D-1 | 30 |
| Example 1-16 | J-16 | A-1/A-2 | 50/50 | B-16 | 10 | C-1/C-2 | 1100/200 | D-1 | 30 |
| Example 1-17 | J-17 | A-1/A-2 | 50/50 | B-17 | 10 | C-1/C-2 | 1100/200 | D-1 | 30 |
| Example 1-18 | J-18 | A-1/A-2 | 50/50 | B-18 | 10 | C-1/C-2 | 1100/200 | D-1 | 30 |
| Example 1-19 | J-19 | A-1/A-2 | 50/50 | B-19 | 10 | C-1/C-2 | 1100/200 | D-1 | 30 |
| Example 1-20 | J-20 | A-1/A-2 | 50/50 | B-20 | 10 | C-1/C-2 | 1100/200 | D-1 | 30 |
| Example 1-21 | J-21 | A-1/A-2 | 50/50 | B-21 | 10 | C-1/C-2 | 1100/200 | D-1 | 30 |
| Example 1-22 | J-22 | A-1/A-2 | 50/50 | B-22 | 10 | C-1/C-2 | 1100/200 | D-1 | 30 |
| Example 1-23 | J-23 | A-1/A-2 | 50/50 | B-23 | 10 | C-1/C-2 | 1100/200 | D-1 | 30 |
| Example 1-24 | J-24 | A-1/A-2 | 50/50 | B-24 | 10 | C-1/C-2 | 1100/200 | D-1 | 30 |
| Example 1-25 | J-25 | A-1/A-2 | 50/50 | B-25 | 10 | C-1/C-2 | 1100/200 | D-1 | 30 |
| Example 1-26 | J-26 | A-1/A-2 | 50/50 | B-26 | 10 | C-1/C-2 | 1100/200 | D-1 | 30 |
| Example 1-27 | J-27 | A-1/A-2 | 50/50 | B-27 | 10 | C-1/C-2 | 1100/200 | D-1 | 30 |
| Example 1-28 | J-28 | A-1/A-2 | 50/50 | B-28 | 10 | C-1/C-2 | 1100/200 | D-1 | 30 |
| Example 1-29 | J-29 | A-1/A-2 | 50/50 | B-29 | 10 | C-1/C-2 | 1100/200 | D-1 | 30 |
| Example 1-30 | J-30 | A-1/A-2 | 50/50 | B-30 | 10 | C-1/C-2 | 1100/200 | D-1 | 30 |
| Example 1-31 | J-31 | A-1/A-2 | 50/50 | B-31 | 10 | C-1/C-2 | 1100/200 | D-1 | 30 |
| Example 1-32 | J-32 | A-1/A-2 | 50/50 | B-32 | 10 | C-1/C-2 | 1100/200 | D-1 | 30 |
| Example 1-33 | J-33 | A-1/A-2 | 50/50 | B-33 | 10 | C-1/C-2 | 1100/200 | D-1 | 30 |
| Example 1-34 | J-34 | A-1/A-2 | 50/50 | B-34 | 10 | C-1/C-2 | 1100/200 | D-1 | 30 |
| Example 1-35 | J-35 | A-1/A-2 | 50/50 | B-35 | 10 | C-1/C-2 | 1100/200 | D-1 | 30 |
| Example 1-36 | J-36 | A-1/A-2 | 50/50 | B-36 | 10 | C-1/C-2 | 1100/200 | D-1 | 30 |
| Example 1-37 | J-37 | A-1/A-2 | 50/50 | B-37 | 10 | C-1/C-2 | 1100/200 | D-1 | 30 |
| Example 1-38 | J-38 | A-1/A-2 | 50/50 | B-38 | 10 | C-1/C-2 | 1100/200 | D-1 | 30 |
| Example 1-39 | J-39 | A-1/A-2 | 50/50 | B-39 | 10 | C-1/C-2 | 1100/200 | D-1 | 30 |
| Example 1-40 | J-40 | A-1/A-2 | 50/50 | B-40 | 10 | C-1/C-2 | 1100/200 | D-1 | 30 |
| Comparative | CJ-1 | A-1/A-2 | 50/50 | — | — | C-1/C-2 | 1100/200 | D-1 | 30 |
| Example 1-1 | | | | | | | | | |

TABLE 2

| | Composition | | | Acid generating | | | | Crosslinking | | Acid diffusion | |
|---|---|---|---|---|---|---|---|---|---|---|---|
| | for forming | Polymer [A] | | agent [B] | | Solvent [C] | | agent [D] | | controlling agent [E] | |
| | resist | | Content | | Content | | Content | | Content | | Content |
| | underlayer | | (parts by | | (parts by | | (parts by | | (parts by | | (parts by |
| | film | Type | mass) | Type | mass) | Type | mass) | Type | mass) | Type | mass) |
| Example 1-41 | J-41 | A-1/A-3 | 50/50 | B-41 | 10 | C-1/C-2 | 1100/200 | D-1 | 30 | — | — |
| Example 1-42 | J-42 | A-1/A-3 | 50/50 | B-42 | 10 | C-1/C-2 | 1100/200 | D-1 | 30 | — | — |
| Example 1-43 | J-43 | A-1/A-3 | 50/50 | B-43 | 10 | C-1/C-2 | 1100/200 | D-1 | 30 | — | — |
| Example 1-44 | J-44 | A-1/A-3 | 50/50 | B-44 | 10 | C-1/C-2 | 1100/200 | D-1 | 30 | — | — |
| Example 1-45 | J-45 | A-1/A-3 | 50/50 | B-45 | 10 | C-1/C-2 | 1100/200 | D-1 | 30 | — | — |
| Example 1-46 | J-46 | A-1/A-3 | 50/50 | B-46 | 10 | C-1/C-2 | 1100/200 | D-1 | 30 | — | — |
| Example 1-47 | J-47 | A-1/A-3 | 50/50 | B-47 | 10 | C-1/C-2 | 1100/200 | D-1 | 30 | — | — |
| Example 1-48 | J-48 | A-1/A-3 | 50/50 | B-48 | 10 | C-1/C-2 | 1100/200 | D-1 | 30 | — | — |
| Example 1-49 | J-49 | A-1/A-3 | 50/50 | B-49 | 10 | C-1/C-2 | 1100/200 | D-1 | 30 | — | — |
| Example 1-50 | J-50 | A-1/A-3 | 50/50 | B-1 | 10 | C-1/C-2 | 1100/200 | D-1 | 30 | E-1 | 10 |
| Example 1-51 | J-51 | A-1/A-3 | 50/50 | B-2 | 10 | C-1/C-2 | 1100/200 | D-1 | 30 | E-1 | 10 |
| Example 1-52 | J-52 | A-2/A-3 | 50/50 | B-3 | 10 | C-1/C-2 | 1100/200 | D-1 | 30 | E-1 | 10 |
| Example 1-53 | J-53 | A-2/A-3 | 50/50 | B-4 | 10 | C-1/C-2 | 1100/200 | D-1 | 30 | E-1 | 10 |
| Example 1-54 | J-54 | A-2/A-3 | 50/50 | B-5 | 10 | C-1/C-2 | 1100/200 | D-1 | 30 | E-1 | 10 |
| Example 1-55 | J-55 | A-2/A-3 | 50/50 | B-6 | 10 | C-1/C-2 | 1100/200 | D-1 | 30 | E-1 | 10 |
| Example 1-56 | J-56 | A-2/A-3 | 50/50 | B-7 | 10 | C-1/C-2 | 1100/200 | D-1 | 30 | E-1 | 10 |
| Example 1-57 | J-57 | A-2/A-3 | 50/50 | B-8 | 10 | C-1/C-2 | 1100/200 | D-1 | 30 | E-1 | 10 |
| Example 1-58 | J-58 | A-2/A-3 | 50/50 | B-9 | 10 | C-1/C-2 | 1100/200 | D-1 | 30 | E-1 | 10 |
| Example 1-59 | J-59 | A-2/A-3 | 50/50 | B-10 | 10 | C-1/C-2 | 1100/200 | D-1 | 30 | E-1 | 10 |
| Example 1-60 | J-60 | A-2/A-3 | 50/50 | B-11 | 10 | C-1/C-2 | 1100/200 | D-1 | 30 | E-2 | 10 |
| Example 1-61 | J-61 | A-2/A-3 | 50/50 | B-12 | 10 | C-1/C-2 | 1100/200 | D-1 | 30 | E-3 | 10 |
| Example 1-62 | J-62 | A-2/A-3 | 50/50 | B-13 | 10 | C-1/C-2 | 1100/200 | D-1 | 30 | E-4 | 10 |
| Example 1-63 | J-63 | A-2/A-3 | 50/50 | B-14 | 10 | C-1/C-2 | 1100/200 | D-1 | 30 | E-5 | 10 |
| Example 1-64 | J-64 | A-2/A-3 | 50/50 | B-15 | 10 | C-1/C-2 | 1100/200 | D-1 | 30 | E-6 | 10 |
| Example 1-65 | J-65 | A-2/A-3 | 50/50 | B-16 | 10 | C-1/C-2 | 1100/200 | D-1 | 30 | E-7 | 10 |
| Example 1-66 | J-66 | A-2/A-3 | 50/50 | B-17 | 10 | C-1/C-2 | 1100/200 | D-1 | 30 | E-8 | 10 |
| Example 1-67 | J-67 | A-2/A-3 | 50/50 | B-18 | 10 | C-1/C-2 | 1100/200 | D-1 | 30 | E-9 | 10 |
| Example 1-68 | J-68 | A-2/A-3 | 50/50 | B-19 | 10 | C-1/C-2 | 1100/200 | D-1 | 30 | E-1 | 10 |
| Example 1-69 | J-69 | A-2/A-3 | 50/50 | B-20 | 10 | C-1/C-2 | 1100/200 | D-1 | 30 | E-1 | 10 |
| Example 1-70 | J-70 | A-2/A-3 | 50/50 | B-21 | 10 | C-1/C-2 | 1100/200 | D-1 | 30 | E-1 | 10 |
| Example 1-71 | J-71 | A-2/A-3 | 50/50 | B-22 | 10 | C-1/C-2 | 1100/200 | D-1 | 30 | E-1 | 10 |
| Example 1-72 | J-72 | A-2/A-3 | 50/50 | B-23 | 10 | C-1/C-2 | 1100/200 | D-1 | 30 | E-1 | 10 |
| Example 1-73 | J-73 | A-2/A-3 | 50/50 | B-24 | 10 | C-1/C-2 | 1100/200 | D-1 | 30 | E-1 | 10 |
| Example 1-74 | J-74 | A-2/A-3 | 50/50 | B-25 | 10 | C-1/C-2 | 1100/200 | D-1 | 30 | E-1 | 10 |
| Example 1-75 | J-75 | A-2/A-3 | 50/50 | B-26 | 10 | C-1/C-2 | 1100/200 | D-1 | 30 | E-1 | 10 |
| Example 1-76 | J-76 | A-2/A-3 | 50/50 | B-27 | 10 | C-1/C-2 | 1100/200 | D-1 | 30 | E-1 | 10 |
| Example 1-77 | J-77 | A-2/A-3 | 50/50 | B-28 | 10 | C-1/C-2 | 1100/200 | D-1 | 30 | E-1 | 10 |
| Example 1-78 | J-78 | A-2/A-3 | 50/50 | B-29 | 10 | C-1/C-2 | 1100/200 | D-1 | 30 | E-1 | 10 |
| Example 1-79 | J-79 | A-2/A-3 | 50/50 | B-30 | 10 | C-1/C-2 | 1100/200 | D-1 | 30 | E-1 | 10 |
| Example 1-80 | J-80 | A-2/A-3 | 50/50 | B-31 | 10 | C-1/C-2 | 1100/200 | D-1 | 30 | E-1 | 10 |
| Example 1-81 | J-81 | A-2/A-3 | 50/50 | B-32 | 10 | C-1/C-2 | 1100/200 | D-1 | 30 | E-1 | 10 |

### Evaluation

Using the compositions for forming a resist underlayer film prepared as described above, the rectangularity of a resist pattern was evaluated by the following method. The evaluation results are given in the following Tables 3 and 4.

### Preparation of Resist Composition for EUV Exposure (R-1)

A resist composition for EUV exposure (R-1) was obtained by mixing 100 parts by mass of a polymer having a structural unit (1) derived from 4-hydroxystyrene, a structural unit (2) derived from styrene, and a structural unit (3) derived from 4-t-butoxystyrene (content ratio of each structural unit: (1)/(2)/(3)=65/5/30 (mol %)), 1.0 parts by mass of triphenylsulfonium trifluoromethanesulfonate as a radiation-sensitive acid generating agent, and 4, 400 parts by mass of ethyl lactate and 1, 900 parts by mass of propylene glycol monomethyl ether acetate each as a solvent, and filtering the obtained solution through a filter having a pore size of 0.2 μm.

### Pattern Rectangularity (EUV Exposure)

A material for forming an organic underlayer film (“HM8006”, available from JSR Corporation) was applied on a 12-inch silicon wafer by spin-coating using a spin-coater (“CLEAN TRACK ACT12”, available from Tokyo Electron Ltd.), and thereafter heating was conducted at 250° C. for 60 sec to form an organic underlayer film having an average thickness of 100 nm. To the organic underlayer film was applied a composition for forming a silicon-containing film (“NFC SOG080” manufactured by JSR Corporation), heated at 220° C. for 60 sec, and then cooled at 23° C. for 30 sec. Thus, a silicon-containing film having an average thickness of 20 nm was formed. To the silicon-containing film formed as described above was applied the composition for forming a resist underlayer film prepared above, heated at 250° C. for 60 sec, and then cooled at 23° C. for 30 sec. Thus, a resist underlayer film having an average thickness of 5 nm was formed. To the resist underlayer film formed as described above was applied a resist composition for EUV exposure (R-1), heated at 130° C. for 60 sec, and then cooled at 23° C. for 30 sec. Thus, a resist film having an average thickness of 50 nm was formed. Next, the resist film was irradiated with extreme ultraviolet rays using an EUV scanner (“TWINSCAN NXE:3300B”, available from ASML Co. (NA=0.3; Sigma=0.9; quadrupole illumination, with a 1:1 line and space mask having a line width of 16 nm in terms of a dimension on wafer)). After the irradiation with the extreme ultraviolet rays, the substrate was heated at 110° C. for 60 sec, followed by cooling at 23° C. for 60 sec. Thereafter, development was performed by a paddle method using a 2.38% by mass aqueous tetramethylammonium hydroxide solution (20° C. to 25° C.), followed by washing with water and drying, thereby affording a substrate for evaluation having a resist pattern formed thereon. A scanning electron microscope (“SU8220” available from Hitachi High-Technologies Corporation) was used for length measurement and observation of the resist pattern of the substrate for evaluation. The pattern rectangularity was evaluated as “A” (good) when the cross-sectional shape of the pattern was rectangular, and “B” (poor) when trailing was present in the cross section of the pattern.

TABLE 3

| | Composition for | | |
|---|---|---|---|
| | forming resist | Resist composition | Pattern |
| | underlayer film | for EUV exposure | rectangularity |
| Example 2-1 | J-1 | R-1 | A |
| Example 2-2 | J-2 | R-1 | A |
| Example 2-3 | J-3 | R-1 | A |
| Example 2-4 | J-4 | R-1 | A |
| Example 2-5 | J-5 | R-1 | A |
| Example 2-6 | J-6 | R-1 | A |
| Example 2-7 | J-7 | R-1 | A |
| Example 2-8 | J-8 | R-1 | A |
| Example 2-9 | J-9 | R-1 | A |
| Example 2-10 | J-10 | R-1 | A |
| Example 2-11 | J-11 | R-1 | A |
| Example 2-12 | J-12 | R-1 | A |
| Example 2-13 | J-13 | R-1 | A |
| Example 2-14 | J-14 | R-1 | A |
| Example 2-15 | J-15 | R-1 | A |
| Example 2-16 | J-16 | R-1 | A |
| Example 2-17 | J-17 | R-1 | A |
| Example 2-18 | J-18 | R-1 | A |
| Example 2-19 | J-19 | R-1 | A |
| Example 2-20 | J-20 | R-1 | A |
| Example 2-21 | J-21 | R-1 | A |
| Example 2-22 | J-22 | R-1 | A |
| Example 2-23 | J-23 | R-1 | A |
| Example 2-24 | J-24 | R-1 | A |
| Example 2-25 | J-25 | R-1 | A |
| Example 2-26 | J-26 | R-1 | A |
| Example 2-27 | J-27 | R-1 | A |
| Example 2-28 | J-28 | R-1 | A |
| Example 2-29 | J-29 | R-1 | A |
| Example 2-30 | J-30 | R-1 | A |
| Example 2-31 | J-31 | R-1 | A |
| Example 2-32 | J-32 | R-1 | A |
| Example 2-33 | J-33 | R-1 | A |
| Example 2-34 | J-34 | R-1 | A |
| Example 2-35 | J-35 | R-1 | A |
| Example 2-36 | J-36 | R-1 | A |
| Example 2-37 | J-37 | R-1 | A |
| Example 2-38 | J-38 | R-1 | A |
| Example 2-39 | J-39 | R-1 | A |
| Example 2-40 | J-40 | R-1 | A |
| Comparative | CJ-1 | R-1 | B |
| Example 2-1 | | | |

TABLE 4

| | Composition for | | |
|---|---|---|---|
| | forming resist | Resist composition | Pattern |
| | underlayer film | for EUV exposure | rectangularity |
| Example 2-41 | J-41 | R-1 | A |
| Example 2-42 | J-42 | R-1 | A |
| Example 2-43 | J-43 | R-1 | A |
| Example 2-44 | J-44 | R-1 | A |
| Example 2-45 | J-45 | R-1 | A |
| Example 2-46 | J-46 | R-1 | A |
| Example 2-47 | J-47 | R-1 | A |
| Example 2-48 | J-48 | R-1 | A |
| Example 2-49 | J-49 | R-1 | A |
| Example 2-50 | J-50 | R-1 | A |
| Example 2-51 | J-51 | R-1 | A |
| Example 2-52 | J-52 | R-1 | A |
| Example 2-53 | J-53 | R-1 | A |
| Example 2-54 | J-54 | R-1 | A |
| Example 2-55 | J-55 | R-1 | A |
| Example 2-56 | J-56 | R-1 | A |
| Example 2-57 | J-57 | R-1 | A |
| Example 2-58 | J-58 | R-1 | A |
| Example 2-59 | J-59 | R-1 | A |
| Example 2-60 | J-60 | R-1 | A |
| Example 2-61 | J-61 | R-1 | A |
| Example 2-62 | J-62 | R-1 | A |
| Example 2-63 | J-63 | R-1 | A |
| Example 2-64 | J-64 | R-1 | A |
| Example 2-65 | J-65 | R-1 | A |
| Example 2-66 | J-66 | R-1 | A |
| Example 2-67 | J-67 | R-1 | A |
| Example 2-68 | J-68 | R-1 | A |
| Example 2-69 | J-69 | R-1 | A |
| Example 2-70 | J-70 | R-1 | A |
| Example 2-71 | J-71 | R-1 | A |
| Example 2-72 | J-72 | R-1 | A |
| Example 2-73 | J-73 | R-1 | A |
| Example 2-74 | J-74 | R-1 | A |
| Example 2-75 | J-75 | R-1 | A |
| Example 2-76 | J-76 | R-1 | A |
| Example 2-77 | J-77 | R-1 | A |
| Example 2-78 | J-78 | R-1 | A |
| Example 2-79 | J-79 | R-1 | A |
| Example 2-80 | J-80 | R-1 | A |
| Example 2-81 | J-81 | R-1 | A |

### Evaluation

Using the compositions for forming a resist underlayer film prepared as described above, the rectangularity of a resist pattern was evaluated by the following method. The evaluation results are given in the following Tables 5 and 6.

### Preparation of Resist Composition for EUV Exposure (R-2)

### Synthesis of Compound

The compound (S-1) to be used for the preparation of a resist composition for EUV exposure (R-2) was synthesized by the following procedure. In a reaction vessel, 6.5 parts by mass of isopropyltin trichloride was added while stirring 150 mL of a 0.5 N aqueous sodium hydroxide solution, and a reaction was carried out for 2 hours. The precipitate formed was collected by filtration, washed twice with 50 parts by mass of water, and then dried, affording a compound (S-1). The compound (S-1) was an oxidized hydroxide product of a hydrolysate of isopropyltin trichloride (the oxidized hydroxide product contained i-PrSnO_{(3/2-x/2)} (OH)ₓ (0<x<3) as a structural unit).

2 parts by mass of the compound (S-1) synthesized above and 98 parts by mass of propylene glycol monoethyl ether were mixed, and the resulting mixture was subjected to removal of residual water with activated 4 Å molecular sieve, and then filtered through a filter having a pore size of 0.2 μm. Thus, a resist composition for EUV exposure (R-2) was prepared.

### Pattern Rectangularity (EUV Exposure)

A material for forming an organic underlayer film (“HM8006”, available from JSR Corporation) was applied on a 12-inch silicon wafer by spin-coating using a spin-coater (“CLEAN TRACK ACT12”, available from Tokyo Electron Ltd.), and thereafter heating was conducted at 250° C. for 60 sec to form an organic underlayer film having an average thickness of 100 nm. To the organic underlayer film was applied the composition for forming a resist underlayer film prepared above, heated at 220° C. for 60 sec, and then cooled at 23° C. for 30 sec. Thus, a resist underlayer film having an average thickness of 5 nm was formed. To the resist underlayer film was applied the resist composition for EUV exposure (R-2) by the spin coating method using the spin coater described above, and after a lapse of a prescribed time, heated at 90° C. for 60 sec, and then cooled at 23° C. for 30 sec. Thus, a resist film having an average thickness of 35 nm was formed. The resist film was exposed to light using an EUV scanner (“TWINSCAN NXE:3300B”, available from ASML Co. (NA=0.3; Sigma=0.9; quadrupole illumination, with a 1:1 line and space mask having a line width of 16 nm in terms of a dimension on wafer)). After the exposure, the substrate was heated at 110° C. for 60 sec, and subsequently cooled at 23° C. for 60 sec. Thereafter, development was performed by a paddle method using 2-heptanone (20 to 25° C.), and then dried, affording a substrate for evaluation with a resist pattern formed thereon. A scanning electron microscope (“CG-6300” available from Hitachi High-Tech Corporation) was used for length measurement and observation of the resist pattern of the substrate for evaluation. The pattern rectangularity was evaluated as “A” (good) when the cross-sectional shape of the pattern was rectangular, and “B” (poor) when trailing was present in the cross section of the pattern.

TABLE 5

| | Composition for | | |
|---|---|---|---|
| | forming resist | Resist composition | Pattern |
| | underlayer film | for EUV exposure | rectangularity |
| Example 3-1 | J-1 | R-2 | A |
| Example 3-2 | J-2 | R-2 | A |
| Example 3-3 | J-3 | R-2 | A |
| Example 3-4 | J-4 | R-2 | A |
| Example 3-5 | J-5 | R-2 | A |
| Example 3-6 | J-6 | R-2 | A |
| Example 3-7 | J-7 | R-2 | A |
| Example 3-8 | J-8 | R-2 | A |
| Example 3-9 | J-9 | R-2 | A |
| Example 3-10 | J-10 | R-2 | A |
| Example 3-11 | J-11 | R-2 | A |
| Example 3-12 | J-12 | R-2 | A |
| Example 3-13 | J-13 | R-2 | A |
| Example 3-14 | J-14 | R-2 | A |
| Example 3-15 | J-15 | R-2 | A |
| Example 3-16 | J-16 | R-2 | A |
| Example 3-17 | J-17 | R-2 | A |
| Example 3-18 | J-18 | R-2 | A |
| Example 3-19 | J-19 | R-2 | A |
| Example 3-20 | J-20 | R-2 | A |
| Example 3-21 | J-21 | R-2 | A |
| Example 3-22 | J-22 | R-2 | A |
| Example 3-23 | J-23 | R-2 | A |
| Example 3-24 | J-24 | R-2 | A |
| Example 3-25 | J-25 | R-2 | A |
| Example 3-26 | J-26 | R-2 | A |
| Example 3-27 | J-27 | R-2 | A |
| Example 3-28 | J-28 | R-2 | A |
| Example 3-29 | J-29 | R-2 | A |
| Example 3-30 | J-30 | R-2 | A |
| Example 3-31 | J-31 | R-2 | A |
| Example 3-32 | J-32 | R-2 | A |
| Example 3-33 | J-33 | R-2 | A |
| Example 3-34 | J-34 | R-2 | A |
| Example 3-35 | J-35 | R-2 | A |
| Example 3-36 | J-36 | R-2 | A |
| Example 3-37 | J-37 | R-2 | A |
| Example 3-38 | J-38 | R-2 | A |
| Example 3-39 | J-39 | R-2 | A |
| Example 3-40 | J-40 | R-2 | A |
| Comparative | CJ-1 | R-2 | B |
| Example 3-1 | | | |

TABLE 6

| | Composition for | | |
|---|---|---|---|
| | forming resist | Resist composition | Pattern |
| | underlayer film | for EUV exposure | rectangularity |
| Example 3-41 | J-41 | R-2 | A |
| Example 3-42 | J-42 | R-2 | A |
| Example 3-43 | J-43 | R-2 | A |
| Example 3-44 | J-44 | R-2 | A |
| Example 3-45 | J-45 | R-2 | A |
| Example 3-46 | J-46 | R-2 | A |
| Example 3-47 | J-47 | R-2 | A |
| Example 3-48 | J-48 | R-2 | A |
| Example 3-49 | J-49 | R-2 | A |
| Example 3-50 | J-50 | R-2 | A |
| Example 3-51 | J-51 | R-2 | A |
| Example 3-52 | J-52 | R-2 | A |
| Example 3-53 | J-53 | R-2 | A |
| Example 3-54 | J-54 | R-2 | A |
| Example 3-55 | J-55 | R-2 | A |
| Example 3-56 | J-56 | R-2 | A |
| Example 3-57 | J-57 | R-2 | A |
| Example 3-58 | J-58 | R-2 | A |
| Example 3-59 | J-59 | R-2 | A |
| Example 3-60 | J-60 | R-2 | A |
| Example 3-61 | J-61 | R-2 | A |
| Example 3-62 | J-62 | R-2 | A |
| Example 3-63 | J-63 | R-2 | A |
| Example 3-64 | J-64 | R-2 | A |
| Example 3-65 | J-65 | R-2 | A |
| Example 3-66 | J-66 | R-2 | A |
| Example 3-67 | J-67 | R-2 | A |
| Example 3-68 | J-68 | R-2 | A |
| Example 3-69 | J-69 | R-2 | A |
| Example 3-70 | J-70 | R-2 | A |
| Example 3-71 | J-71 | R-2 | A |
| Example 3-72 | J-72 | R-2 | A |
| Example 3-73 | J-73 | R-2 | A |
| Example 3-74 | J-74 | R-2 | A |
| Example 3-75 | J-75 | R-2 | A |
| Example 3-76 | J-76 | R-2 | A |
| Example 3-77 | J-77 | R-2 | A |
| Example 3-78 | J-78 | R-2 | A |
| Example 3-79 | J-79 | R-2 | A |
| Example 3-80 | J-80 | R-2 | A |
| Example 3-81 | J-81 | R-2 | A |

As can be seen from the results shown in Tables 3 to 6, the resist underlayer films formed from the compositions for forming a resist underlayer film of Examples were superior in pattern rectangularity to the resist underlayer films formed from the compositions for forming a resist underlayer film of Comparative Examples.

By the method for manufacturing a semiconductor substrate of the present disclosure, it is possible to efficiently manufacture a semiconductor substrate because of using a composition for forming a resist underlayer film capable of forming a resist underlayer film superior in pattern rectangularity. When the composition for forming a resist underlayer film of the present disclosure is used, a film superior in pattern rectangularity can be formed. Therefore, they can suitably be used for, for example, producing semiconductor devices expected to be further microfabricated in the future.

Obviously, numerous modifications and variations of the present invention(s) are possible in light of the above teachings. It is therefore to be understood that within the scope of the appended claims, the invention(s) may be practiced otherwise than as specifically described herein.

What is claimed is:

1. A method for manufacturing a semiconductor substrate, the method comprising:
directly or indirectly applying a composition for forming a resist underlayer film to a substrate to forma resist underlayer film;
applying a composition for forming a resist film to the resist underlayer film to form a resist film;
exposing the resist film to radiation; and
developing the exposed resist film,
wherein the composition for forming a resist underlayer film comprises:
a polymer;
an acid generating agent; and
a solvent, and
the resist underlayer film has a film thickness of 6 nm or less.

2. The method according to claim 1, wherein the radiation is an extreme ultraviolet ray.

3. The method according to claim 1, wherein a developer to be used in developing the exposed resist film is a basic solution.

4. The method according to claim 1, wherein the acid generating agent is represented by formula (c): 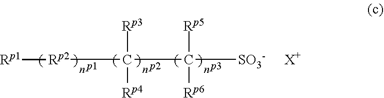
wherein, in the formula (c), R^{p1} is a hydrogen atom, a fluorine atom, or a monovalent organic group having 1 to 20 carbon atoms; R^{p2} is a divalent linking group; R^{p3} and R^{p4} are each independently a hydrogen atom, a fluorine atom, a monovalent hydrocarbon group having 1 to 20 carbon atoms, or a monovalent fluorinated hydrocarbon group having 1 to 20 carbon atoms; R^{p5} and R^{p6} are each independently a fluorine atom or a monovalent fluorinated hydrocarbon group having 1 to 20 carbon atoms; n^{p1} is an integer of 0 to 10; n^{p2} is an integer of 0 to 10; n^{p3} is an integer of 1 to 10; when n^{p1} is 2 or more, a plurality of R^{p2}s are identical or different; when n^{p2} is 2 or more, a plurality of R^{p3}s are identical or different, and a plurality of R^{p4}s are identical or different; when n^{p3} is 2 or more, a plurality of R^{p5}s are identical or different, and a plurality of R^{p6}s are identical or different; and X⁺ is a monovalent radiation-sensitive onium cation.

5. The method according to claim 1, further comprising:
forming a silicon-containing film directly or indirectly on the substrate before applying the composition for forming a resist underlayer film.

6. The method according to claim 1, wherein the resist underlayer film has the film thickness of 4 nm or less.

7. The method according to claim 1, wherein the resist underlayer film has the film thickness of 0.5 to 4 nm.

8. A composition suitable for forming a resist underlayer film having a film thickness of 6 nm or less, the composition comprising:
a polymer;
an acid generating agent; and
a solvent.
